(19) United States
(12) Patent Application Publication
(10) Pub. No.: US 2026/0173436 A1
(43) Pub. Date: Jun. 18, 2026

(54) HORIZONTAL TRANSPORT GAA TUNNEL FETS

(71) Applicant: International Business Machines Corporation, Armonk, NY (US)

(72) Inventors: Andrew Gaul, Halfmoon, NY (US); Julien Frougier, Albany, NY (US); Andrew Mark Greene, Slingerlands, NY (US); Shogo Mochizuki, Mechanicville, NY (US); Ruilong Xie, Niskayuna, NY (US)

(21) Appl. No.: 18/983,894

(22) Filed: Dec. 17, 2024

(51) Int. Cl. H10D 30/00; H10D 30/01; H10D 62/00; H10D 62/10; H10D 62/13; H10D 62/17; H10D 62/834; H10D 62/854; H10D 84/85

(52) U.S. Cl. CPC H10D 30/502; H10D 30/0191; H10D 62/021; H10D 62/121; H10D 62/151; H10D 62/235; H10D 62/834; H10D 62/854; H10D 84/851

(57) ABSTRACT

P-i-n junction semiconductor devices and a method of forming a p-i-n junction semiconductor device are presented. A p-i-n junction semiconductor device comprises an extrinsically doped drain, a first extrinsically doped source, a first intrinsically doped tunneling channel coupled between the extrinsically doped drain and the first extrinsically doped source, a second extrinsically doped source, a second intrinsically doped tunneling channel coupled between the extrinsically doped drain and the second extrinsically doped source, and a gate coupled to both the first intrinsically doped tunneling channel and the second intrinsically doped tunneling channel. An axis defined by the extrinsically doped drain, an axis defined by the first extrinsically doped source, and an axis defined by the second extrinsically doped source are all substantially parallel.

### BACKGROUND

The disclosure relates generally to the electrical, electronic, and computer arts, and more specifically, to fabricating semiconductor devices.

There is an ever-increasing demand for internet of things (IOT) apparatuses. With increased IOT demand comes increased demand for low-power semiconductor devices.

Industry-standard CMOS devices utilize thermionic injection, which fundamentally limits subthreshold swing (SS) to 60 mV/dec (@ 300K. This limit on the subthreshold swing (SS) hinders the creation of low power devices (Vdd<0.5V).

Tunneling FETs (TFETs) are a promising candidate for alternate transport/switching mechanisms to achieve steep-slope/low-power operation. It would be desirable to provide a scalable manufacturing process and design for tunneling FETs.

### SUMMARY

The illustrative examples present horizontal transport GAA tunnel FETs. According to an illustrative embodiment, a p-i-n junction semiconductor device is presented. A p-i-n junction semiconductor device comprises an extrinsically doped drain, a first extrinsically doped source, a first intrinsically doped tunneling channel coupled between the extrinsically doped drain and the first extrinsically doped source, a second extrinsically doped source, a second intrinsically doped tunneling channel coupled between the extrinsically doped drain and the second extrinsically doped source, and a gate coupled to both the first intrinsically doped tunneling channel and the second intrinsically doped tunneling channel. An axis defined by the extrinsically doped drain, an axis defined by the first extrinsically doped source, and an axis defined by the second extrinsically doped source are all substantially parallel.

According to another illustrative embodiment, a p-i-n junction semiconductor device is presented. The p-i-n junction semiconductor device comprises an extrinsically doped drain; an extrinsically doped source; a first intrinsically doped tunneling channel coupled between the extrinsically doped drain and the extrinsically doped source; a second intrinsically doped tunneling channel coupled between the extrinsically doped drain and the extrinsically doped source; and a gate coupled to both the first intrinsically doped tunneling channel and the second intrinsically doped tunneling channel, wherein an axis defined by the extrinsically doped drain and an axis defined by the extrinsically doped source are substantially parallel, and wherein the second intrinsically doped tunneling channel is stacked with regard to the first intrinsically doped tunneling channel along both the axis defined by the extrinsically doped drain and the axis defined by the extrinsically doped source.

According to yet another illustrative embodiment, a method of forming a p-i-n junction semiconductor device is presented. A plurality of canyons for sources and drains is etched through a nanosheet stack of channel material sheets and sacrificial layers. The sacrificial layers of the nanosheet stack are etched out. A dielectric sacrificial material is deposited in the nanosheet stack. The plurality of canyons is etched into the dielectric sacrificial material. The method laterally etches into the dielectric sacrificial material in the plurality of canyons. An inner spacer is deposited into the plurality of canyons. The plurality of canyons is etched into the inner spacer. The method laterally etches into the channel material sheets past the inner spacer in at least one canyon of the plurality of canyons to form lateral recesses. One of a source or a drain is epitaxially grown in the at least one canyon including the lateral recesses.

In view of the foregoing, techniques of the present invention can provide substantial beneficial technical effects. For example, the lateral etching enables the gate directly contacting the entire circumference of the source-channel interface. Additionally, replacing sacrificial layers with a dielectric sacrificial material enables Epi growth in a single crystal orientation.

Some embodiments may not have these potential advantages, and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is an illustration of a cross-sectional view of a p-i-n junction semiconductor device in a nFET region and a pFET region of a semiconductor wafer after a fabrication stage in accordance with an illustrative embodiment;

FIG. 2 is an illustration of a cross-sectional view of a semiconductor device in a nFET region and a pFET region of a semiconductor wafer after a fabrication stage in accordance with an illustrative embodiment;

FIG. 3 is an illustration of a cross-sectional view of a semiconductor device in a nFET region and a pFET region of a semiconductor wafer after a spacer formation and etch back in accordance with an illustrative embodiment;

FIG. 4 is an illustration of a cross-sectional view of a semiconductor device in a nFET region and a pFET region of a semiconductor wafer after Fin recess formation in accordance with an illustrative embodiment;

FIG. 5 is an illustration of a cross-sectional view of a semiconductor device in a nFET region and a pFET region of a semiconductor wafer after sacrificial channel etch out in accordance with an illustrative embodiment;

FIG. 6 is an illustration of a cross-sectional view of a semiconductor device in a nFET region and a pFET region of a semiconductor wafer after sacrificial channel deposition and etch back in accordance with an illustrative embodiment;

FIG. 7 is an illustration of a cross-sectional view of a semiconductor device in a nFET region and a pFET region of a semiconductor wafer after inner spacer indent, deposition, and etch back in accordance with an illustrative embodiment;

FIG. 8 is an illustration of a cross-sectional view of a semiconductor device in a nFET region and a pFET region of a semiconductor wafer after a junction liner deposition in accordance with an illustrative embodiment;

FIG. 9 is an illustration of a cross-sectional view of a semiconductor device in a nFET region and a pFET region of a semiconductor wafer with pFET drain patterning in accordance with an illustrative embodiment;

FIG. 10 is an illustration of a cross-sectional view of a semiconductor device in a nFET region and a pFET region of a semiconductor wafer after pFET liner strip in accordance with an illustrative embodiment;

FIG. 11 is an illustration of a cross-sectional view of a semiconductor device in a nFET region and a pFET region of a semiconductor wafer after pFET patterning strip in accordance with an illustrative embodiment;

FIG. 12 is an illustration of a cross-sectional view of a semiconductor device in a nFET region and a pFET region of a semiconductor wafer after a lateral push in accordance with an illustrative embodiment;

FIG. 13 is an illustration of a cross-sectional view of a semiconductor device in a nFET region and a pFET region of a semiconductor wafer after a drain growth in accordance with an illustrative embodiment;

FIG. 14 is an illustration of a cross-sectional view of a semiconductor device in a nFET region and a pFET region of a semiconductor wafer after a liner strip in accordance with an illustrative embodiment;

FIG. 15 is an illustration of a cross-sectional view of a semiconductor device in a nFET region and a pFET region of a semiconductor wafer after a junction liner deposition in accordance with an illustrative embodiment;

FIG. 16 is an illustration of a cross-sectional view of a semiconductor device in a nFET region and a pFET region of a semiconductor wafer with pFET source patterning in accordance with an illustrative embodiment;

FIG. 17 is an illustration of a cross-sectional view of a semiconductor device in a nFET region and a pFET region of a semiconductor wafer after pFET liner strip in accordance with an illustrative embodiment;

FIG. 18 is an illustration of a cross-sectional view of a semiconductor device in a nFET region and a pFET region of a semiconductor wafer after pFET patterning strip in accordance with an illustrative embodiment;

FIG. 19 is an illustration of a cross-sectional view of a semiconductor device in a nFET region and a pFET region of a semiconductor wafer after a lateral push and source growth in accordance with an illustrative embodiment;

FIG. 20 is an illustration of a cross-sectional view of a semiconductor device in a nFET region and a pFET region of a semiconductor wafer after a liner strip in accordance with an illustrative embodiment;

FIG. 21 is an illustration of a cross-sectional view of a semiconductor device in a nFET region and a pFET region of a semiconductor wafer after a liner deposition and with nFET drain patterning in accordance with an illustrative embodiment;

FIG. 22 is an illustration of a cross-sectional view of a semiconductor device in a nFET region and a pFET region of a semiconductor wafer after nFET liner strip in accordance with an illustrative embodiment;

FIG. 23 is an illustration of a cross-sectional view of a semiconductor device in a nFET region and a pFET region of a semiconductor wafer after nFET patterning strip in accordance with an illustrative embodiment;

FIG. 24 is an illustration of a cross-sectional view of a semiconductor device in a nFET region and a pFET region of a semiconductor wafer after a lateral push in accordance with an illustrative embodiment;

FIG. 25 is an illustration of a cross-sectional view of a semiconductor device in a nFET region and a pFET region of a semiconductor wafer after channel re-growth in accordance with an illustrative embodiment;

FIG. 26 is an illustration of a cross-sectional view of a semiconductor device in a nFET region and a pFET region of a semiconductor wafer after drain growth in accordance with an illustrative embodiment;

FIG. 27 is an illustration of a cross-sectional view of a semiconductor device in a nFET region and a pFET region of a semiconductor wafer after liner strip in accordance with an illustrative embodiment;

FIG. 28 is an illustration of a cross-sectional view of a semiconductor device in a nFET region and a pFET region of a semiconductor wafer after a liner deposition and with nFET source patterning in accordance with an illustrative embodiment;

FIG. 29 is an illustration of a cross-sectional view of a semiconductor device in a nFET region and a pFET region of a semiconductor wafer after nFET liner strip in accordance with an illustrative embodiment;

FIG. 30 is an illustration of a cross-sectional view of a semiconductor device in a nFET region and a pFET region of a semiconductor wafer after nFET patterning strip in accordance with an illustrative embodiment;

FIG. 31 is an illustration of a cross-sectional view of a semiconductor device in a nFET region and a pFET region of a semiconductor wafer after a lateral push in accordance with an illustrative embodiment;

FIG. 32 is an illustration of a cross-sectional view of a semiconductor device in a nFET region and a pFET region of a semiconductor wafer after source growth in accordance with an illustrative embodiment;

FIG. 33 is an illustration of a cross-sectional view of a semiconductor device in a nFET region and a pFET region of a semiconductor wafer after liner strip in accordance with an illustrative embodiment;

FIG. 34 is an illustration of a cross-sectional view of a semiconductor device in a nFET region and a pFET region of a semiconductor wafer after gate formation in accordance with an illustrative embodiment;

FIG. 35 is an illustration of a cross-sectional view of a p-i-n junction semiconductor device in a nFET region and a pFET region of a semiconductor wafer after a fabrication stage in accordance with an illustrative embodiment; and

FIG. 36 is an illustration of a top view of a p-i-n junction semiconductor device in a nFET region and a pFET region of a semiconductor wafer after a fabrication stage in accordance with an illustrative embodiment.

### DETAILED DESCRIPTION

The illustrative examples recognize and take into account several considerations. The illustrative examples recognize and take into account that tunneling FETs have been used to create functioning inverter arrays at Vdd=0.2V. The illustrative examples recognize and take into account that III-V tunneling FETs integrated on Si<100> produce desirable performance (high Id, low SS). The illustrative examples recognize and take into account that a scalable template for heterogenous manufacturing is not conventionally available.

The illustrative examples present a p-i-n junction semiconductor device and a method of forming a p-i-n junction semiconductor device that provide horizontal transport GAA tunneling FETs.

It should be understood in advance that although this invention includes a detailed description of exemplary GAA nanosheet tunneling FET architectures, embodiments of the invention are not limited to the particular tunneling FET architectures described in this specification. Rather, embodiments of the present invention are capable of being implemented in conjunction with any other type of nanosheet/nanowire FET architecture now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Transistors are semiconductor devices commonly found in a wide variety of integrated circuits (ICs). A transistor is effectively a switch. When a voltage is applied to a gate of the transistor that is greater than a threshold voltage, the switch is turned on, and current flows through the transistor. When the voltage at the gate is less than the threshold voltage, the switch is off, and current does not flow through the transistor.

Semiconductor devices are formed using active regions of a wafer. The active regions are defined by isolation regions used to separate and electrically isolate adjacent semiconductor devices.

A semiconductor wafer includes multiple tunnel FETs, with each tunnel FET having a source, a drain, a channel and a gate. The channel connects the source and the drain, and electrical current flows through the channel from the source to the drain. Electrical current flow is induced in the channel by a voltage applied at the gate. The size of a tunnel FET is related to the electrical conductivity of the tunnel FET channel material. If the channel material has relatively high conductivity, the FET can be made correspondingly smaller. One method of forming a relatively small FET is to form the channel as a series of nanostructures using nanosheets or nanowires.

Gate-all-around (GAA) nanosheet channel FETs enable feature scaling beyond current planar CMOS technology. In its basic form, a nanosheet-based FET includes a source region, a drain region and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets.

The illustrative examples provide a sacrificial channel material selected to enable controlled growth of Epi layers in the tunneling FETs. In the illustrative examples the nFET and the pFET have different channel materials as well as different source and drain materials and doping.

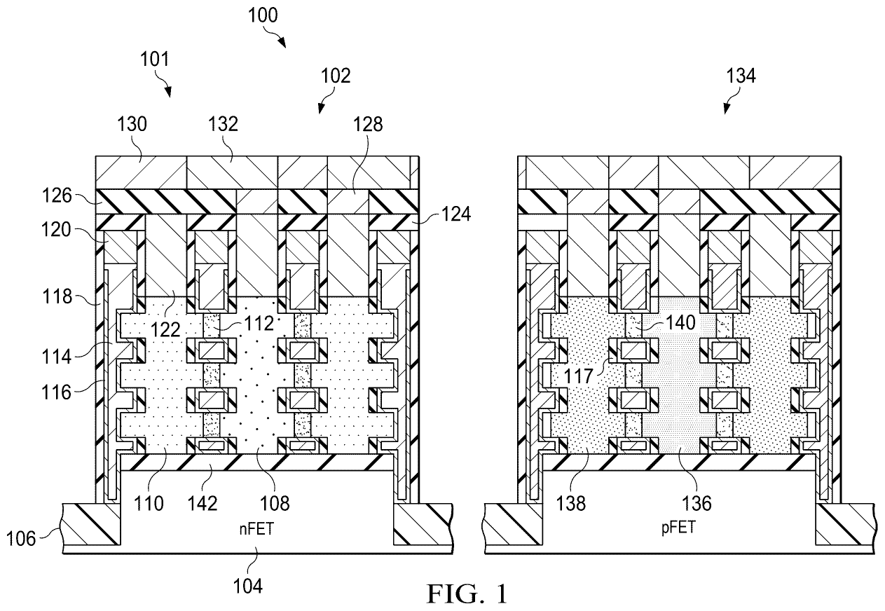

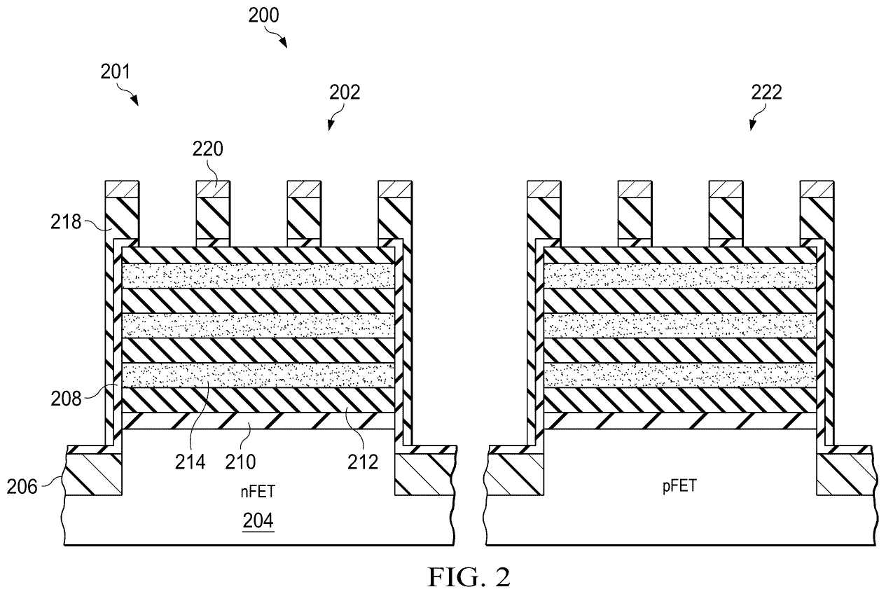

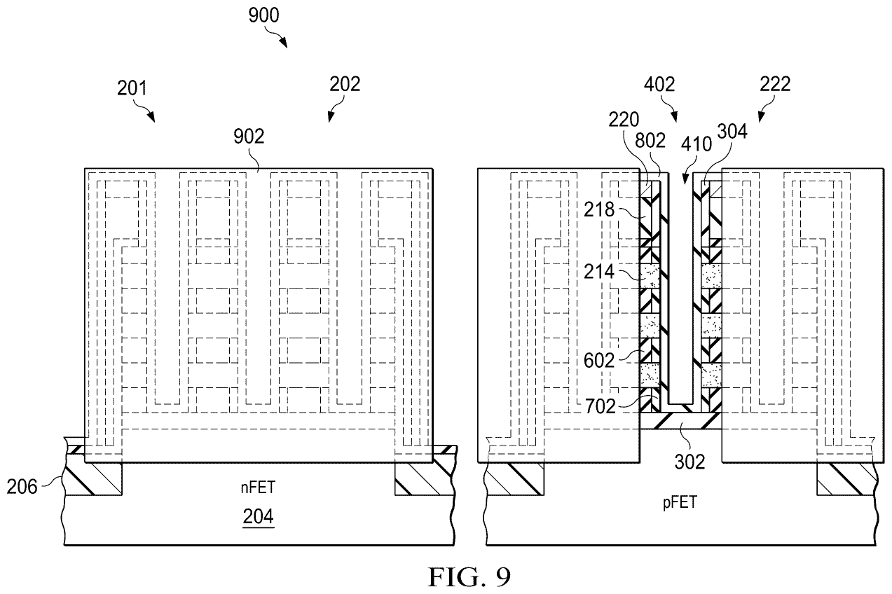

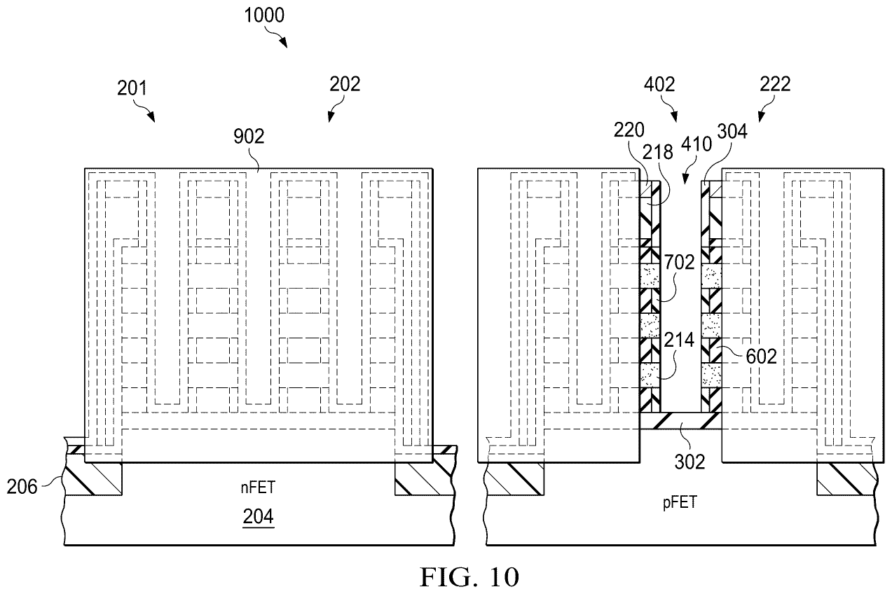

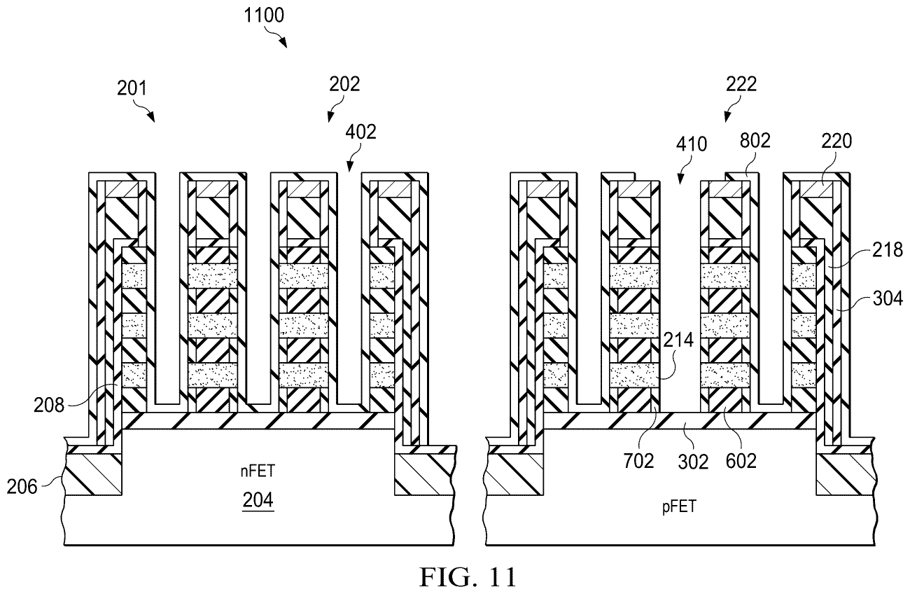

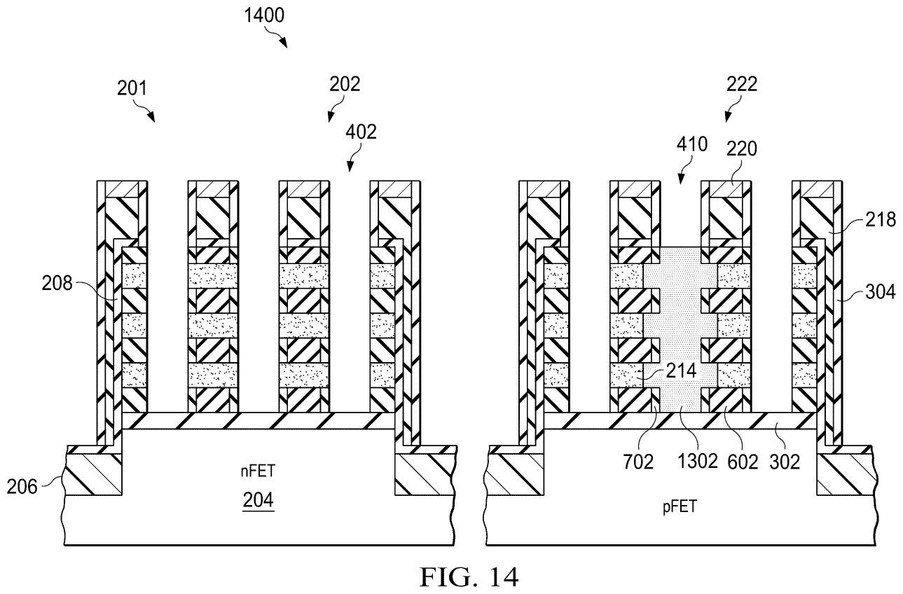

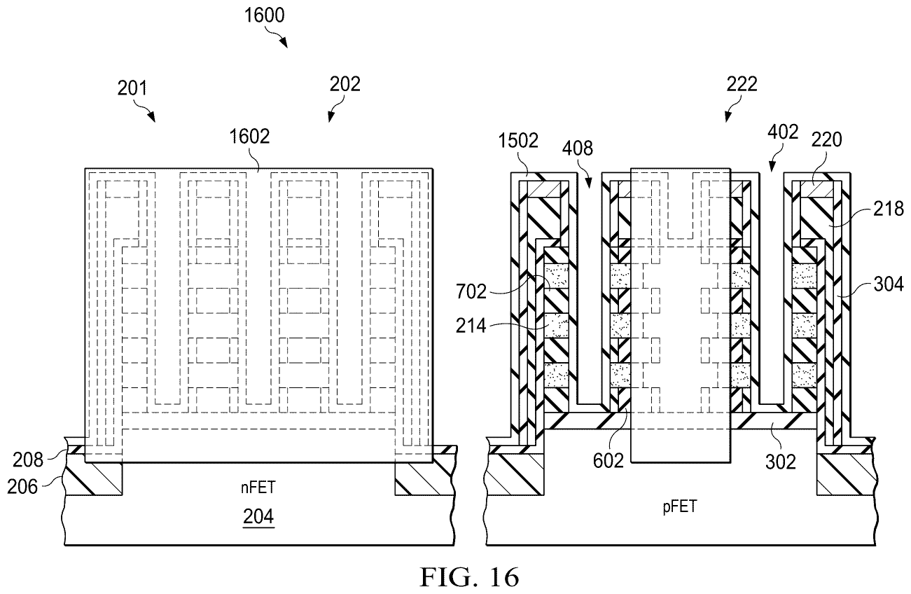

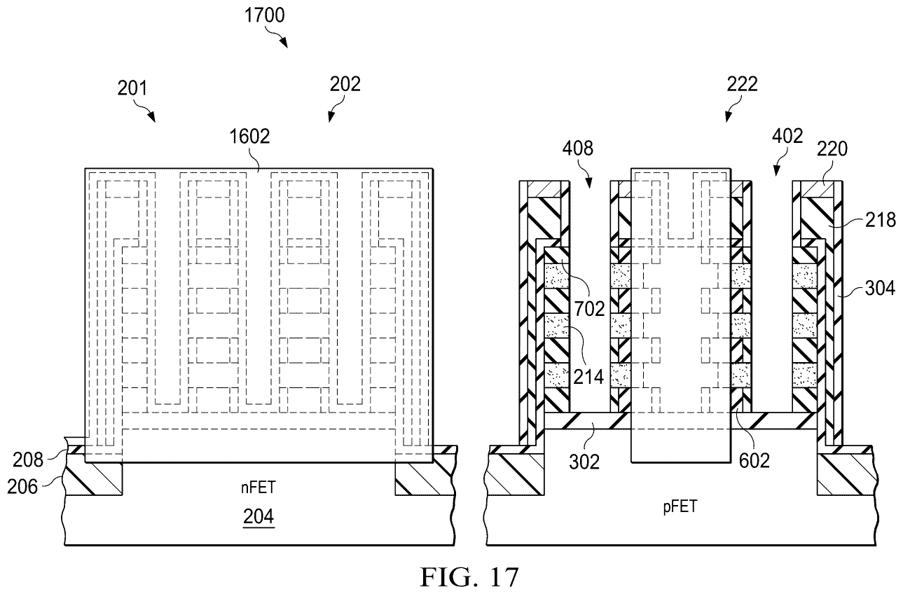

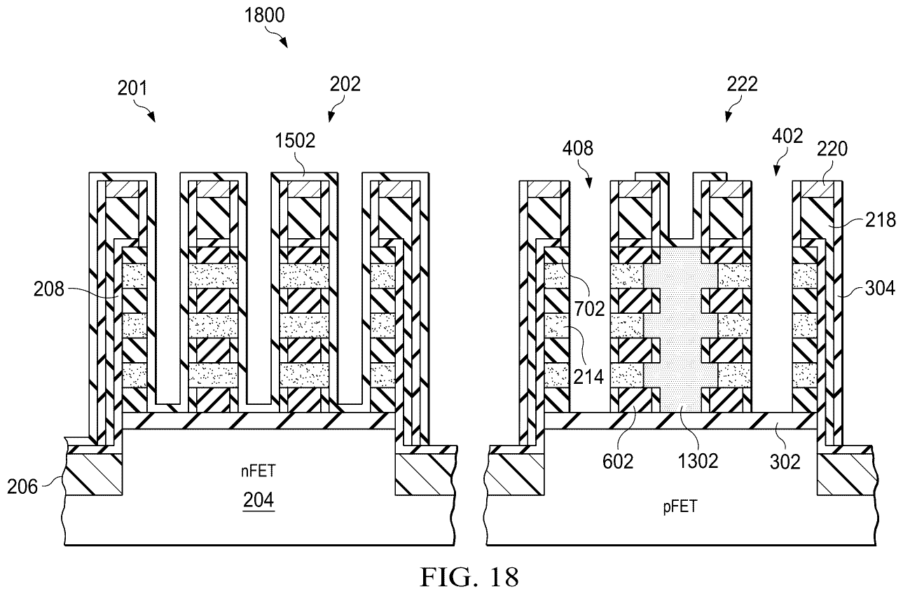

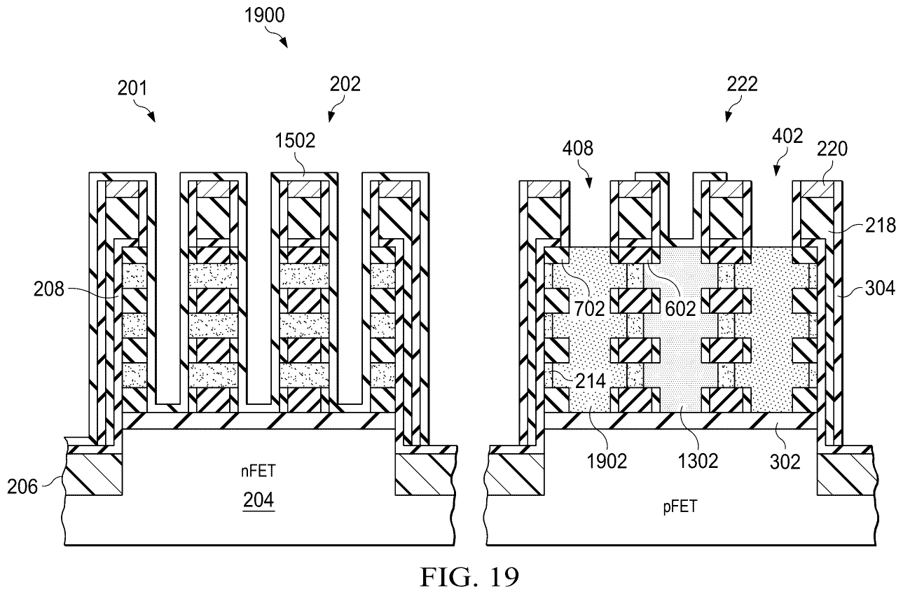

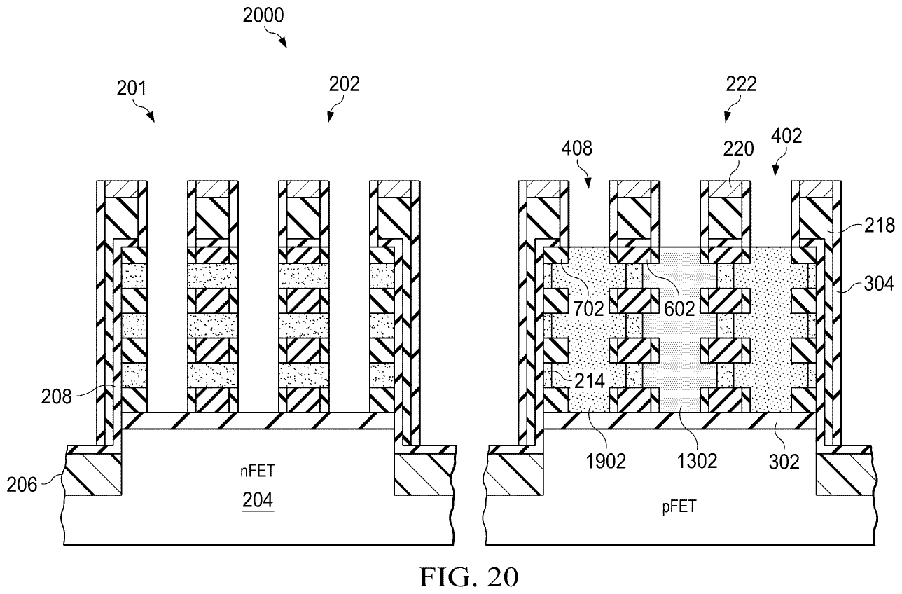

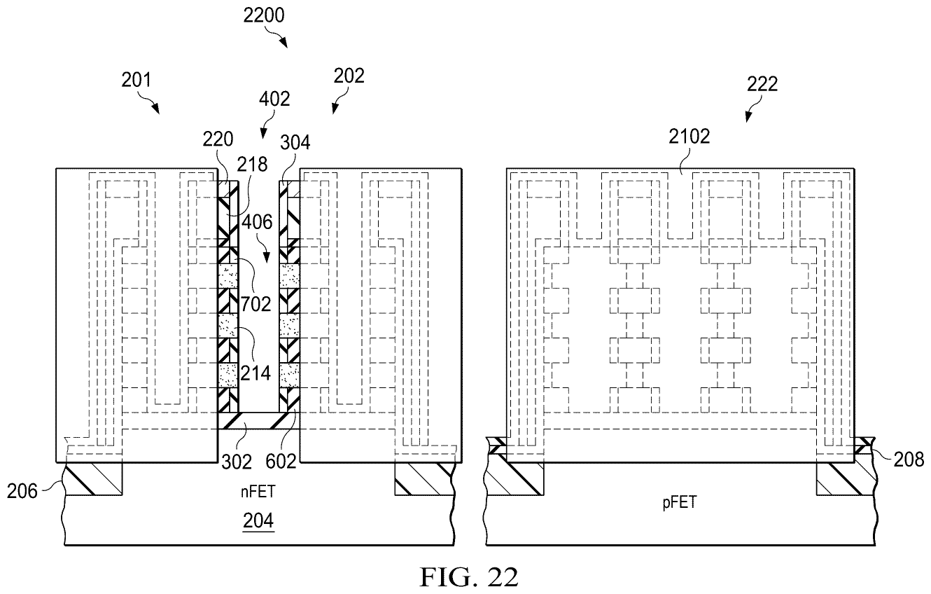

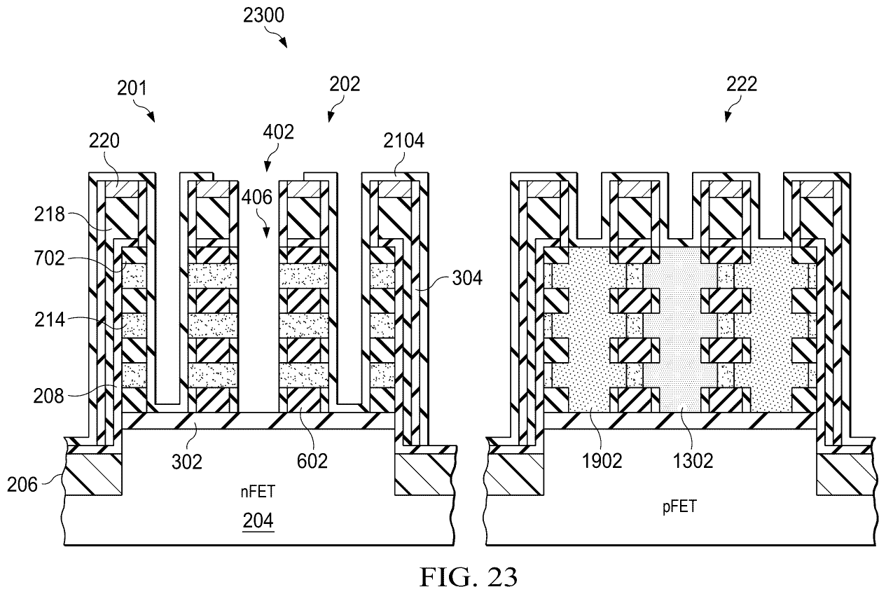

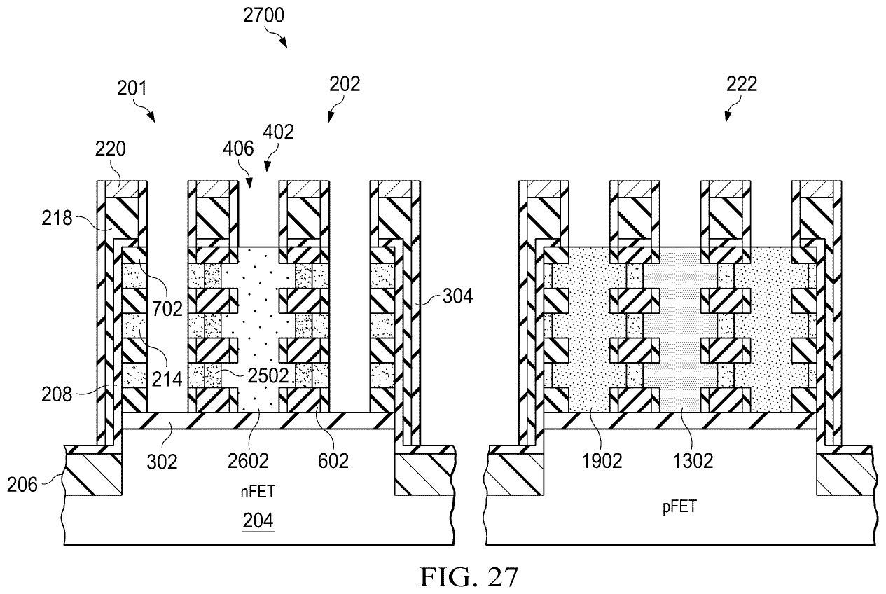

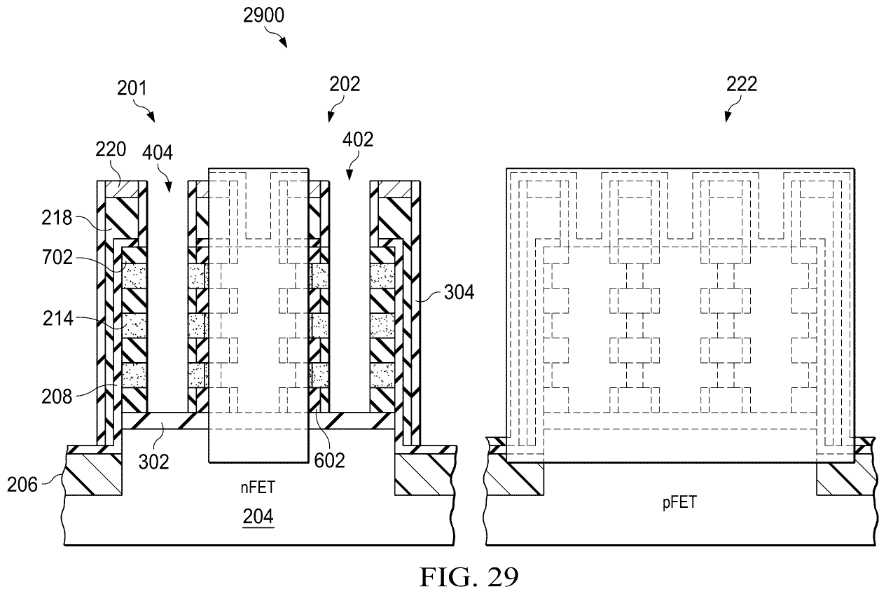

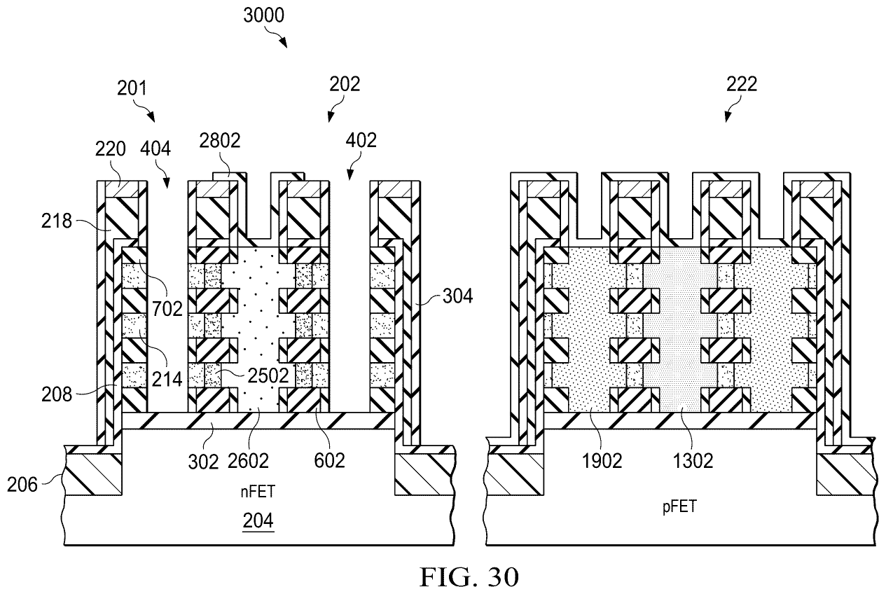

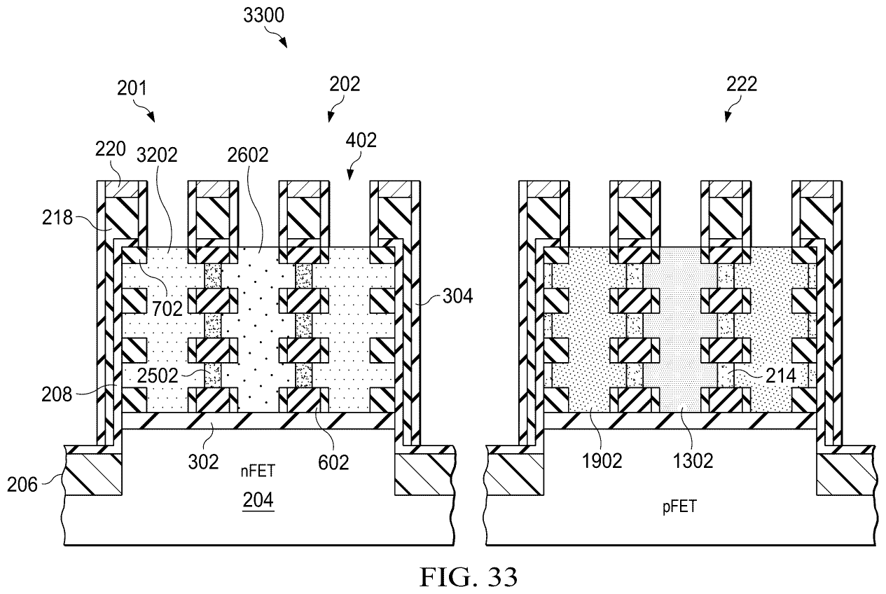

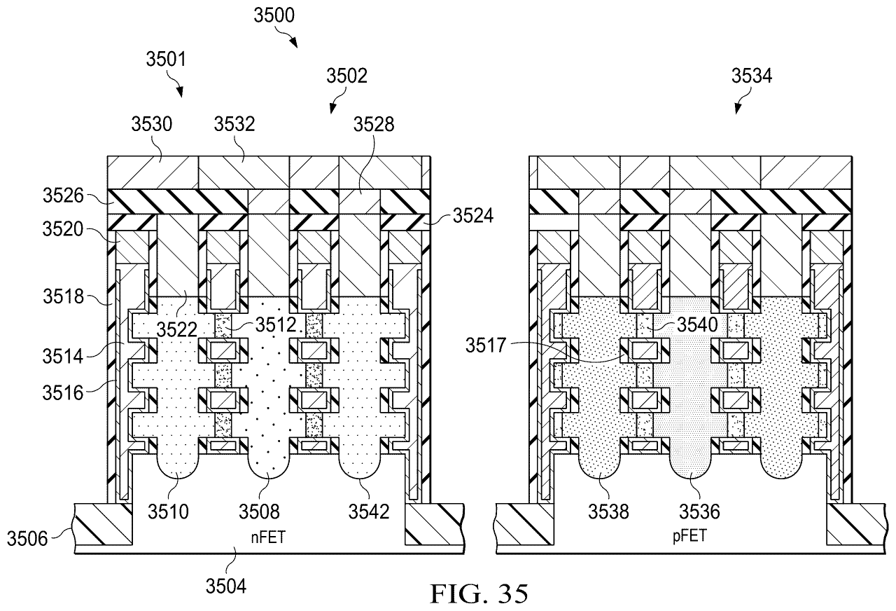

FIGS. 1 and 35 are illustrations of cross-sectional views of a semiconductor structure with one nFET region and one pFET region. FIGS. 2 through 33 are illustrations of a silicon substrate during stages of forming pFET semiconductor devices and nFET semiconductor devices on the same substrate according to one or more embodiments of the present invention. FIGS. 1-35 are cross-sectional views in an X-direction across the Gates inside the active nanosheet devices. Although one nFET region and one pFET region are depicted in the figures, it is contemplated that in practice multiple nFET regions and pFET regions can be provided on the silicon substrate.

Referring to FIG. 1, view 100 includes semiconductor structure 101. Semiconductor structure 101 includes nFET region 102 and pFET region 134. These areas can be co-located on a single substrate. The nFET region 102 and pFET region 134 can be heterogeneously integrated with STI 106 (shallow trench isolation) and SASI 142 (self-aligned substrate isolation layer). The nFET region 102 includes substrate 104. Substrate 104 can be intrinsic p-SI substrate.

Drain 108 is located between two portions of source 110. Drain 108 can be epitaxially deposited n+ InAs. Source 110 can be epitaxially deposited p-GaSb. In this embodiment, there are six of channel 112 located between drain 108 and source 110. Channel 112 can be epitaxially deposited intrinsic n-InAs. There is a gate including WFM 114 (work function metal) and HK 116 (high k dielectric) all around the six of channel 112. Inner spacer 117 is adjacent HK 116 in non-channel sheet areas. Spacer 118 is adjacent HK 116 in areas outboard of source 110.

SAC cap 120 is coupled to a top of WFM 114. Contact (CA) 122 is coupled to a top of drain 108 and a top of source 110. CA ILD 124 is located between contact (CA) 122. Via (VA) ILD 126 is coupled to a top of CA ILD 124. Via (VA) 128 is coupled to a top of contact (CA) 122. Metal 1 (M1) ILD 130 is coupled to a top of via (VA) ILD 126. Metal 1 (layer (M1) 132 is coupled to a top of via (VA) ILD 126 and a top of via (VA) 128.

The pFET region 134 is structurally similar except for the via connections and some of the materials. Drain 136 is located between source 138. Drain 136 can be epitaxially deposited p+Si. Source 138 can be epitaxially deposited n+InAs. In this embodiment, there are six of channel 140 located between drain 136 and source 138. Channel 140 can be epitaxially deposited intrinsic p-Si. Of course, embodiments of this disclosure are not limited to the examples shown in FIG. 1.

Referring to either nFET region 102 or pFET region 134, the depicted embodiment is a p-i-n junction semiconductor device that includes: an extrinsically doped drain; a first extrinsically doped source; a first intrinsically doped tunneling channel coupled between the extrinsically doped drain and the first extrinsically doped source; a second extrinsically doped source; a second intrinsically doped tunneling channel coupled between the extrinsically doped drain and the second extrinsically doped source; and a gate coupled to both the first intrinsically doped tunneling channel and the second intrinsically doped tunneling channel. An axis defined by the extrinsically doped drain, an axis defined by the first extrinsically doped source, and an axis defined by the second extrinsically doped source are all substantially parallel. The axis defined by the extrinsically doped drain, the axis defined by the first extrinsically doped source, and the axis defined by the second extrinsically doped source are substantially coplanar. The p-i-n junction semiconductor device also includes: a drain via coupled to the extrinsically doped drain; a gate via coupled to the gate; a first source via coupled to the first extrinsically doped source; and a second source via coupled to the second extrinsically doped source. The p-i-n junction semiconductor device also includes a self-aligned substrate isolation layer coupled between a substrate and all of the extrinsically doped drain, the first extrinsically doped source, and the second extrinsically doped source. The gate includes a work function metal coated with a high k dielectric. Referring to nFET region 102, the first intrinsically doped tunneling channel and the second intrinsically doped tunneling channel include epitaxially deposited intrinsic n-InAs. Referring to pFET region 134, the first intrinsically doped tunneling channel and the second intrinsically doped tunneling channel include epitaxially deposited intrinsic p-Si.

Turning now to FIG. 2, an illustration of a cross-sectional view of a semiconductor device in a nFET region and a pFET region of a semiconductor wafer after a fabrication stage is depicted in accordance with an illustrative embodiment. In view 200, semiconductor structure 201 comprises an alternating series of sacrificial silicon germanium nanosheet layers 212 and silicon nano sheet layers 214. In view 200 nFET region 202 and pFET region 222 are visible. Semiconductor structure 201 comprises substrate 204 with silicon germanium layer 210 and alternating series of sacrificial silicon germanium nanosheet layers 212 and silicon nano sheet layers 214. In some illustrative examples, substrate 204 can take the form of an intrinsic p-Si substrate.

In some illustrative examples, the alternating series of sacrificial silicon germanium nanosheet layers 212 and silicon nano sheet layers 214 are formed by epitaxially growing one layer and then the next until the desired number and desired thicknesses of the nanosheet layers are achieved. Epitaxial materials can be grown from gaseous or liquid precursors. Epitaxial materials can be grown using vapor-phase epitaxy (VPE), molecular beam epitaxy (MBE), liquid-phase epitaxy (LPE), or other suitable process. Epitaxial silicon, silicon germanium, and/or carbon doped silicon (SiC) silicon can be doped during deposition (in-situ doped) by adding dopants, n-type dopants (e.g., phosphorus or arsenic) or p-type dopants (e.g., boron or gallium), depending on the type of transistor.

The terms “epitaxial growth and/or deposition” and “epitaxially formed and/or grown” means the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes at least one of a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

In view 200, STI 206 is present on substrate 204. Engineering gate (EG) oxide 208 is present on alternating series of sacrificial silicon germanium nanosheet layers 212 and silicon nano sheet layers 214. In some illustrative examples, silicon nano sheet layers 214 are intrinsic silicon. Silicon germanium layer 210 can also be referred to as a high Ge % SiGe layer. In some illustrative examples, the high Ge % SiGe layer takes the form of SiGe60.

Asymmetric silicon (aSi) layer 218 and hard mask 220 are present for patterning during the processing and forming of nFET and pFET devices. Asymmetric silicon (aSi) layer 218 and hard mask 220 can be referred to as dummy gates. Asymmetric silicon (aSi) layer 218 and hard mask 220 will be removed to form gate stacks in later processing steps.

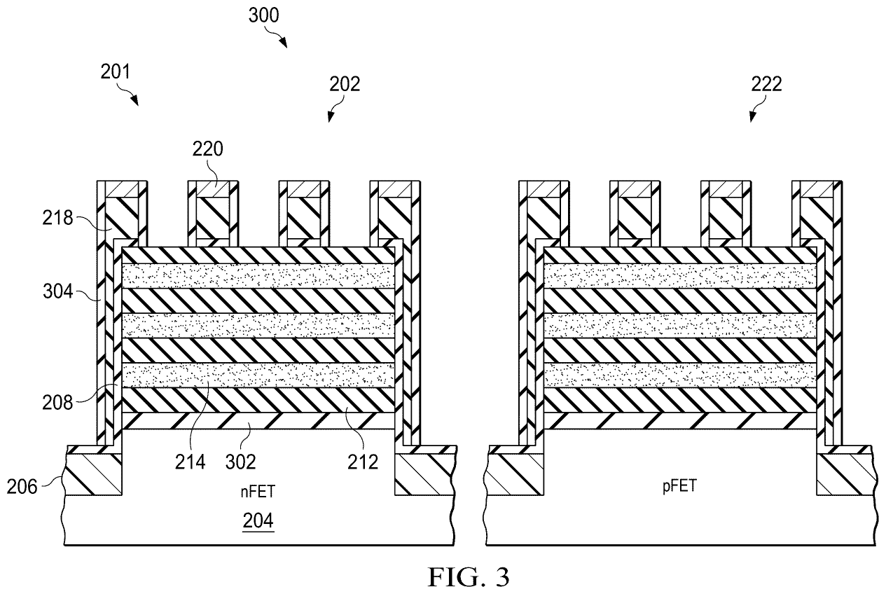

Turning now to FIG. 3, an illustration of a cross-sectional view of a semiconductor device in a nFET region and a pFET region of a semiconductor wafer after a spacer formation and etch back is depicted in accordance with an illustrative embodiment. Between view 200 and view 300, silicon germanium layer 210 has been removed and replaced with spacer material to form self-aligned substrate isolation layer (SASI) 302. Spacer material has been deposited and etched back to form spacers 304. The spacers may be formed of a low-K material such as silicon oxide (SiO), SiON, SiOC, silicon oxycarbonitride (SiOCN), silicoboron carbonitride (SiBCN), or other desirable low-K material.

The depicted semiconductor structure includes SASI layer 302 located between substrate 204 and the later formed gate structure. Replacing sacrificial high Ge % SiGe layer with self-aligned substrate isolation (SASI) layer 302; forming gate spacers 304 on sides of the dummy gates have been performed in view 300.

Moving forward in processing after view 300, source-drain canyons will be formed between the dummy gates. Providing a self-aligned substrate isolation (SASI) layer 302 for optimal fin recess control-can reduce or eliminate over-etch into substrate 204.

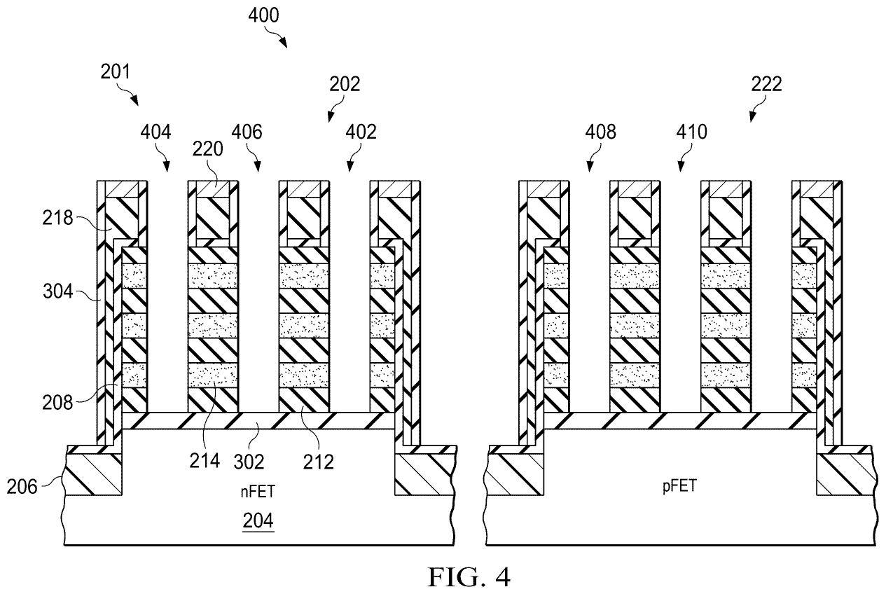

Turning now to FIG. 4, an illustration of a cross-sectional view of a semiconductor device in a nFET region and a pFET region of a semiconductor wafer after Fin recess formation is depicted in accordance with an illustrative embodiment. Plurality of canyons 402 for sources and drains are etched through a nanosheet stack of channel material sheets, silicon nano sheet layers 214, and sacrificial layers, sacrificial silicon germanium nanosheet layers 212. Between view 300 and view 400, plurality of canyons 402 has been etched through sacrificial silicon germanium nanosheet layers 212 and silicon nano sheet layers 214. Plurality of canyons 402 comprises nFET source canyons 404, nFET drain canyon 406, pFET source canyons 408, and pFET drain canyon 410.

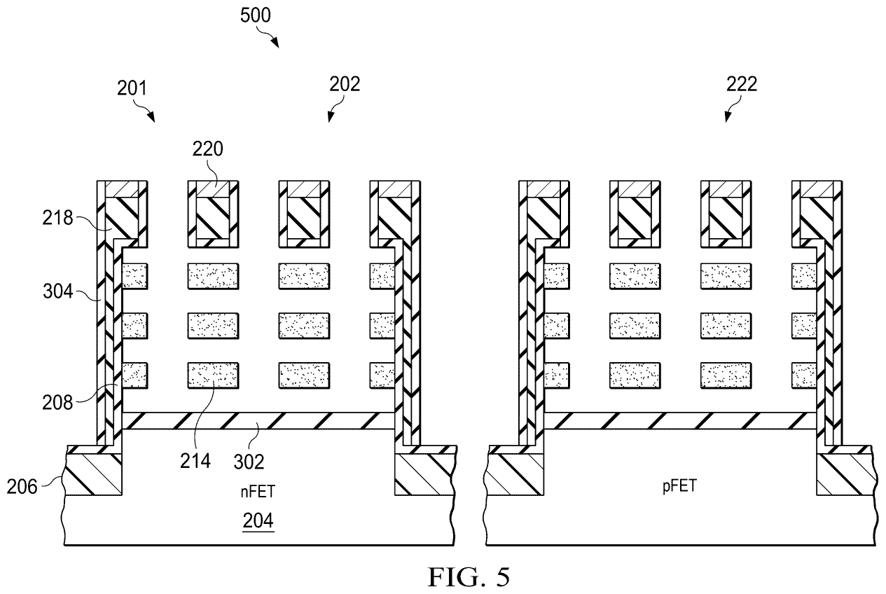

Turning now to FIG. 5, an illustration of a cross-sectional view of a semiconductor device in a nFET region and a pFET region of a semiconductor wafer after sacrificial channel etch out is depicted in accordance with an illustrative embodiment. The method of forming a p-i-n junction semiconductor device has performed etching out the sacrificial layers of the nanosheet stack. In view 500 sacrificial silicon germanium nanosheet layers 212 have been etched out.

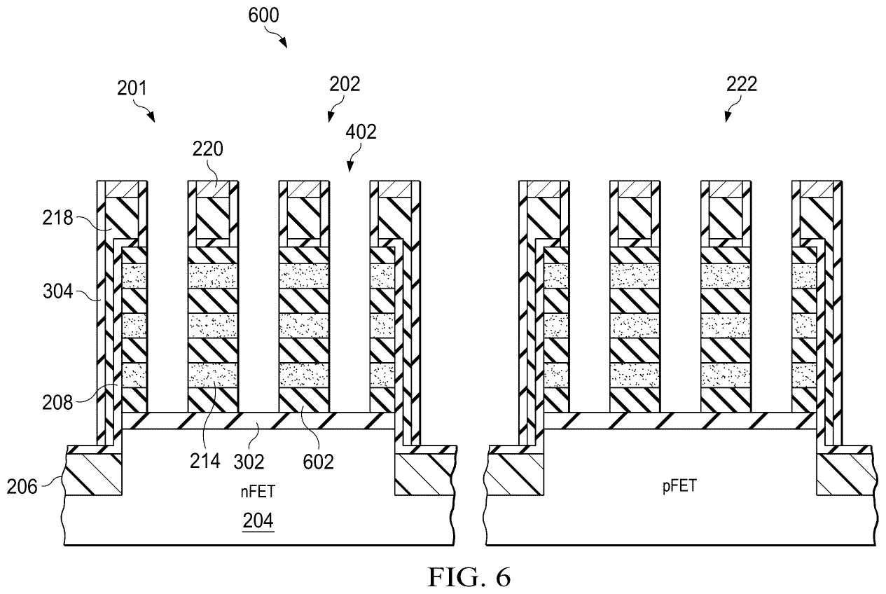

Turning now to FIG. 6, an illustration of a cross-sectional view of a semiconductor device in a nFET region and a pFET region of a semiconductor wafer after sacrificial channel deposition and etch back is depicted in accordance with an illustrative embodiment. The method of forming a p-i-n junction semiconductor device has performed depositing a dielectric sacrificial material in the nanosheet stack. Between view 500 and view 600 a new sacrificial channel material has been deposited to form dielectric channel layers 602. The method of forming a p-i-n junction semiconductor device has also performed etching the plurality of canyons into the dielectric sacrificial material. Plurality of canyons 402 has been etched into dielectric channel layers 602. Dielectric channel layers 602 are formed of a dielectric that Si, Ge, SiGe, InGaAs, GaSb, GaAs, and InAs cannot epitaxially grow upon.

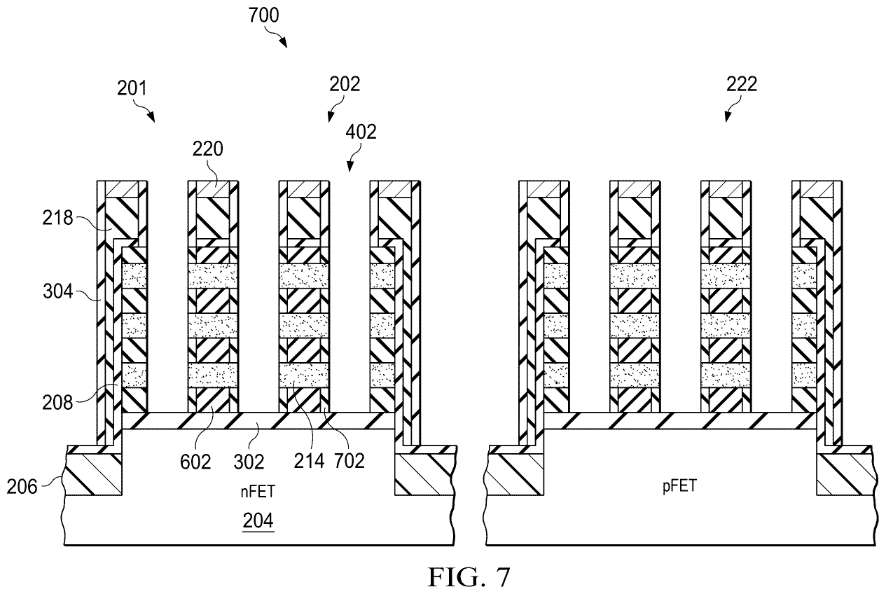

Turning now to FIG. 7, an illustration of a cross-sectional view of a semiconductor device in a nFET region and a pFET region of a semiconductor wafer after inner spacer indent, deposition, and etch back is depicted in accordance with an illustrative embodiment. The method of forming a p-i-n junction semiconductor device has performed laterally etching into the dielectric sacrificial material in the plurality of canyons. The method of forming a p-i-n junction semiconductor device has performed depositing an inner spacer into the plurality of canyons. The method of forming a p-i-n junction semiconductor device has performed etching the plurality of canyons into the inner spacer. Between view 600 and view 700 dielectric channel layers 602 have been laterally etched. A channel spacer material was deposited and plurality of canyons 402 were etched into the spacer material to form channel spacers 702.

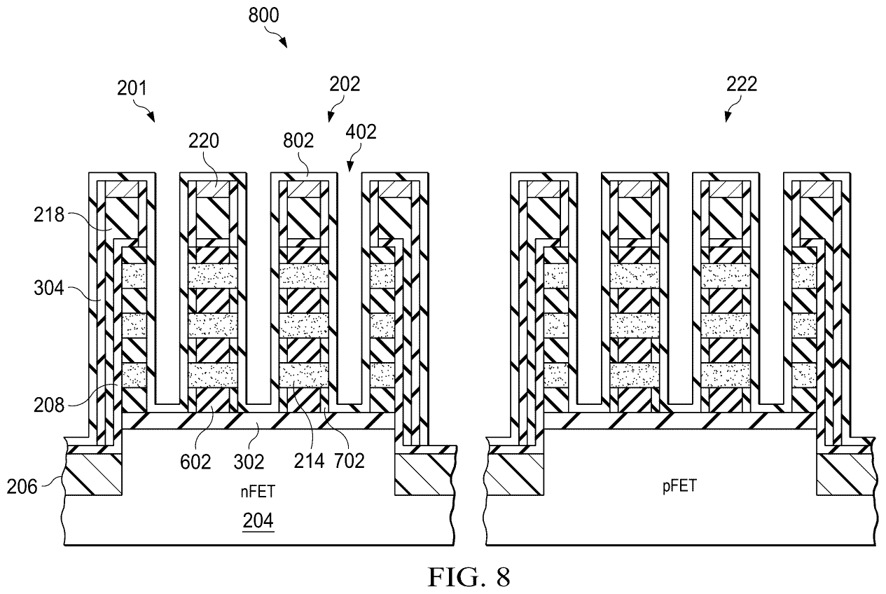

Turning now to FIGS. 8-14, illustrations for processing steps of forming a drain in a pFET region is depicted. In view 800 of FIG. 8, liner 802 is visible covering nFET region 202 and pFET region 222. In some illustrative examples, liner 802 can be described as a p-Epi liner or junction liner. In view 900, pFET drain patterning layer 902 is depicted over semiconductor structure 201. In view 900, pFET drain patterning layer 902 covers nFET region 202 and pFET source canyons 408. In view 900 pFET drain canyon 410 is exposed for etching. In view 1000 liner 802 has been stripped from pFET drain canyon 410 for processing. After stripping liner 802 from pFET drain canyon 410, pFET drain patterning layer 902 is removed, as depicted in view 1100.

The method of forming a p-i-n junction semiconductor device has performed laterally etching into the channel material sheets past the inner spacer in at least one canyon of the plurality of canyons to form lateral recesses. Between view 1100 and view 1200, a lateral etch has been performed. The lateral etch removed portions of silicon nano sheet layers 214 adjacent pFET drain canyon 410. The lateral etch removed portions of silicon nano sheet layers 214 from pFET drain canyon 410 towards pFET source canyon 408. The lateral etch removed portions of silicon nano sheet layers 214 past channel spacers 702. In some illustrative examples, the etching may be referred to as a “lateral push”.

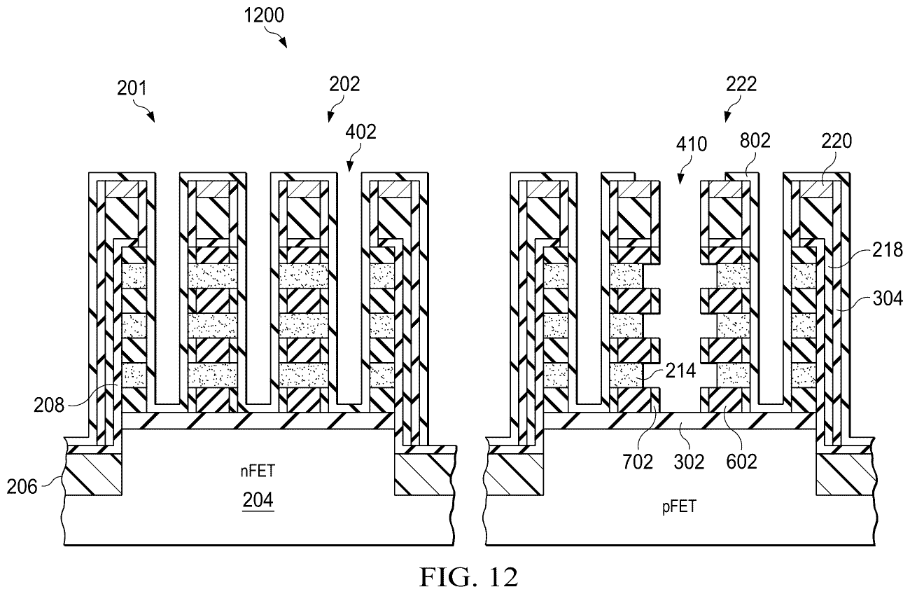

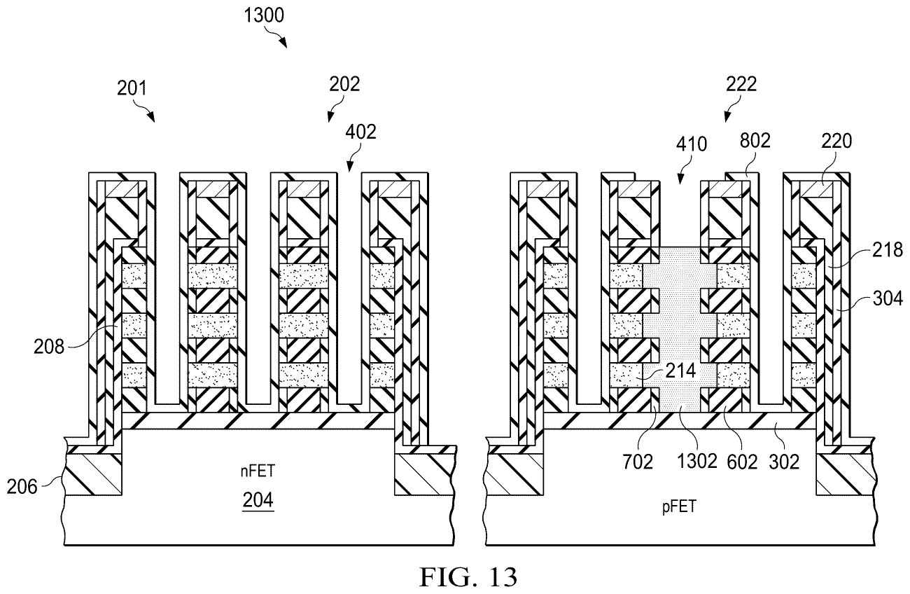

Referencing FIG. 13, an illustration of a cross-sectional view of a semiconductor device in a nFET region and a pFET region of a semiconductor wafer after a drain growth is depicted in accordance with an illustrative embodiment. The method of forming a p-i-n junction semiconductor device has performed epitaxially growing one of a source or a drain in the at least one canyon including the lateral recesses. In view 1300, drain 1302 has been epitaxially grown within pFET drain canyon 410. In some illustrative examples, drain 1302 comprises p+Si. Due to the lateral push depicted in view 1200 of FIG. 12, drain 1302 extends into silicon nano sheet layers 214 past channel spacers 702.

To grow the source and drain regions (S/D regions), canyons of nFET region 202 and pFET region 222 are individually block masked, and then S/D regions are grown. In some illustrative examples, the S/D regions are grown using an epitaxial process. In some illustrative examples, the S/D regions of nFET region 202 and pFET region 222 are epitaxially formed with appropriate in-situ doping to create junctions of the semiconductor device.

As discussed herein, nFETs and pFETs are created by providing different types of dopants in selected regions of the device to form the junction(s). In some illustrative examples, nFETs can be formed by providing, for example, arsenic (As) or phosphorous (P) as the dopant. In some illustrative examples, pFETs can be formed by providing, for example, boron (B) as the dopant.

After depositing drain 1302, a liner strip is performed to remove liner 802 from semiconductor structure 201. In view 1400, liner 802 has been removed and semiconductor structure 201 is ready for further processing to create a source for pFET region 222 and a source and a drain for nFET region 202.

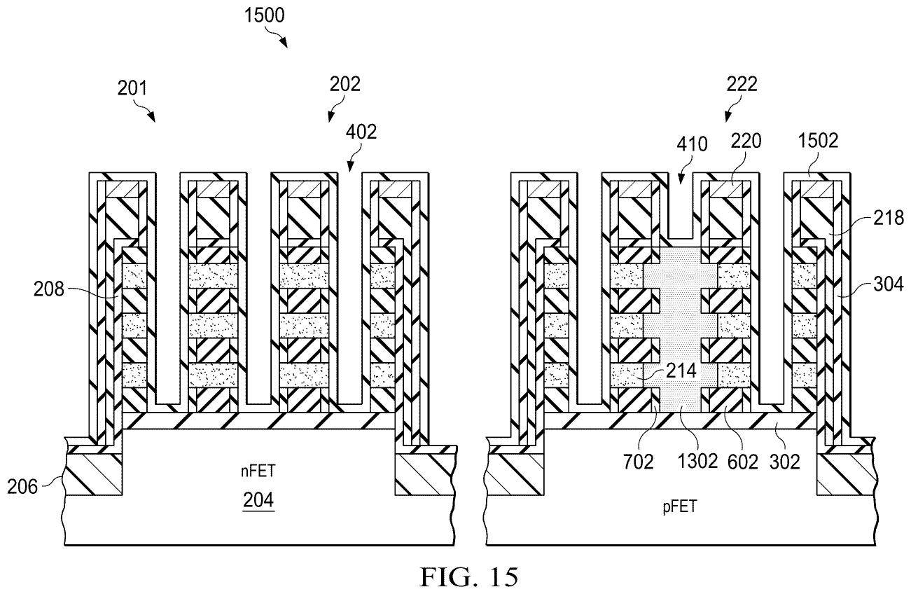

Turning now to FIGS. 15-20, illustrations for processing steps of forming a source in a pFET region are depicted. Illustrations of FIGS. 15-20 depict similar processing to FIGS. 8-14. However, different materials can be utilized in processing for forming a source in pFET region 222.

In view 1500, liner 1502 has been deposited across semiconductor structure 201. In view 1500 liner 1502 is visible covering nFET region 202 and pFET region 222. In view 1600, pFET source patterning layer 1602 is depicted over semiconductor structure 201. In view 1600, pFET source patterning layer 1602 covers nFET region 202 and drain 1302 of pFET region 222. In view 1600 pFET source canyon 408 is exposed for etching. In view 1700 liner 1502 has been stripped from pFET source canyon 408 for processing. After stripping liner 1502 from pFET source canyon 408, pFET source patterning layer 1602 is removed, as depicted in view 1800.

Between view 1800 and view 1900, a lateral etch has been performed. The lateral etch removed portions of silicon nano sheet layers 214 adjacent pFET source canyon 408. The lateral etch removed portions of silicon nano sheet layers 214 from pFET source canyon 408 towards drain 1302. The lateral etch removed portions of silicon nano sheet layers 214 past channel spacers 702. In some illustrative examples, the etching may be referred to as a “lateral push”.

View 1900 is a cross-sectional view of a semiconductor device in a nFET region and a pFET region of a semiconductor wafer after a source growth is depicted in accordance with an illustrative embodiment. In view 1900, source 1902 has been epitaxially grown within pFET source canyon 408. In some illustrative examples, source 1902 comprises InAs. Due to the lateral push depicted in view 1200 of FIG. 12, source 1902 extends into silicon nano sheet layers 214 past channel spacers 702.

After depositing source 1902, a liner strip is performed to remove liner 1502 from semiconductor structure 201. In view 2000, liner 1502 has been removed and semiconductor structure 201 is ready for further processing to create a source and a drain for nFET region 202.

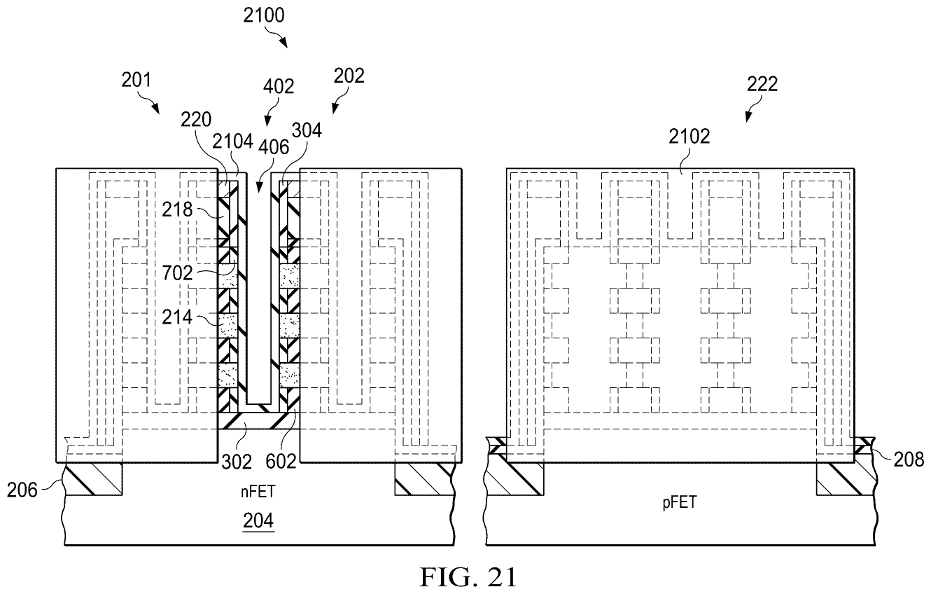

Turning now to FIGS. 21-27, illustrations for processing steps of forming a drain in a nFET region are depicted. In view 2100 of FIG. 21, liner 2104 is visible covering both nFET region 202 and pFET region 222. In view 2100, nFET drain patterning layer 2102 is depicted over semiconductor structure 201. In view 2100, nFET drain patterning layer 2102 covers pFET region 222 and nFET source canyon 404. In view 2100, nFET drain canyon 406 is exposed for etching. In view 2200 liner 2104 has been stripped from nFET drain canyon 406 for processing. After stripping liner 2104 from nFET drain canyon 406, nFET drain patterning layer 2102 is removed, as depicted in view 2300.

Between view 2300 and view 2400, a lateral etch has been performed. The lateral etch removed portions of silicon nano sheet layers 214 adjacent nFET drain canyon 406. The lateral etch removed portions of silicon nano sheet layers 214 from nFET drain canyon 406 towards nFET source canyon 404. The lateral etch removed portions of silicon nano sheet layers 214 past channel spacers 702. In some illustrative examples, the etching may be referred to as a “lateral push”. The lateral push between view 2300 and view 2400 removes a greater amount of silicon nano sheet layers 214 than the lateral push in view 1200.

Between view 2400 and view 2500, channel re-growth has been performed. Channel material is grown on exposed silicon nano sheet layers 214 to form channels 2502. Channels 2502 are epitaxially grown on silicon nano sheet layers 214. In some illustrative examples, channels 2502 are formed of intrinsic n-InAs.

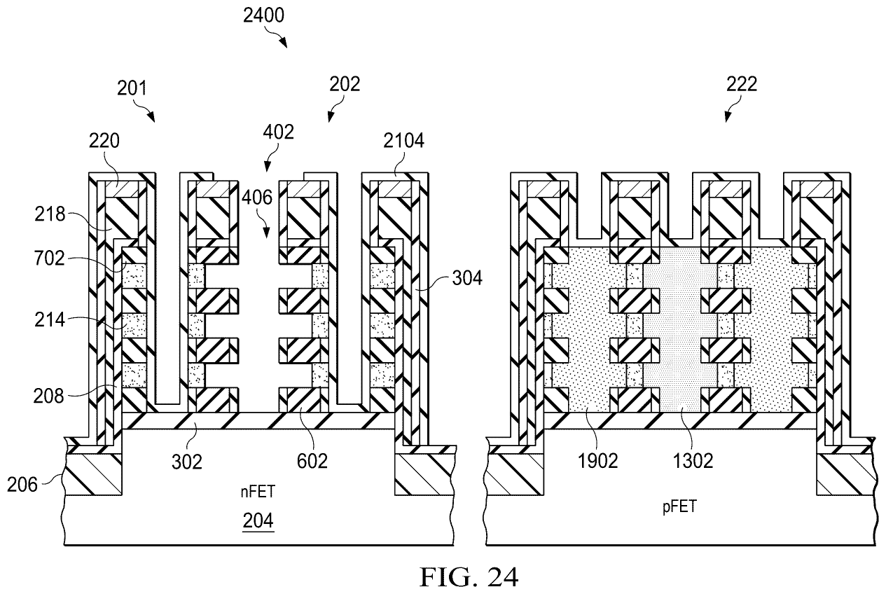

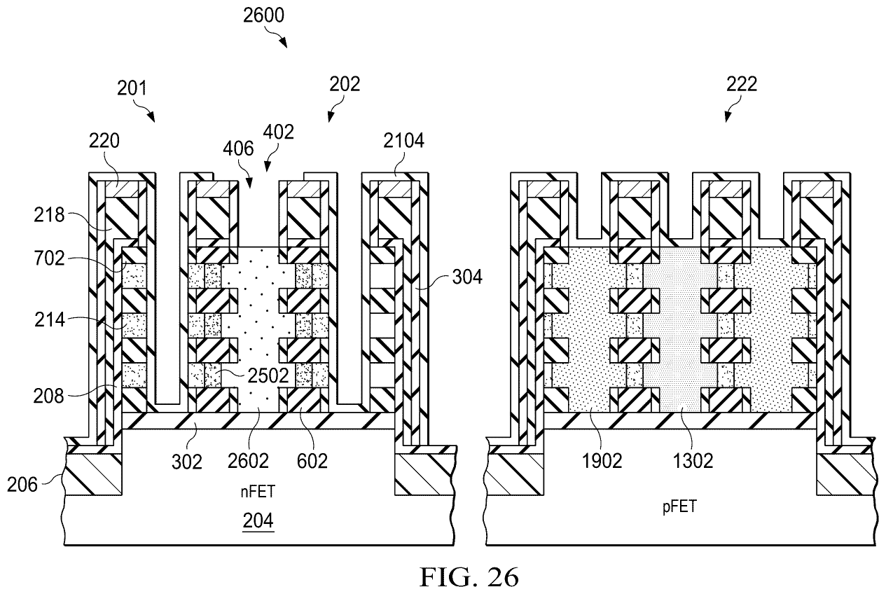

Referencing FIG. 26, an illustration of a cross-sectional view of a semiconductor device in a nFET region and a pFET region of a semiconductor wafer after a drain growth is depicted in accordance with an illustrative embodiment. In view 2600, drain 2602 has been epitaxially grown within nFET drain canyon 406. In some illustrative examples, drain 2602 comprises n+InAs. Due to the lateral push depicted in view 2400 of FIG. 24, drain 2602 extends into silicon nano sheet layers 214 past channel spacers 702.

After depositing drain 2602, a liner strip is performed to remove liner 2104 from semiconductor structure 201. In view 2700, liner 2104 has been removed and semiconductor structure 201 is ready for further processing to create a source for nFET region 202.

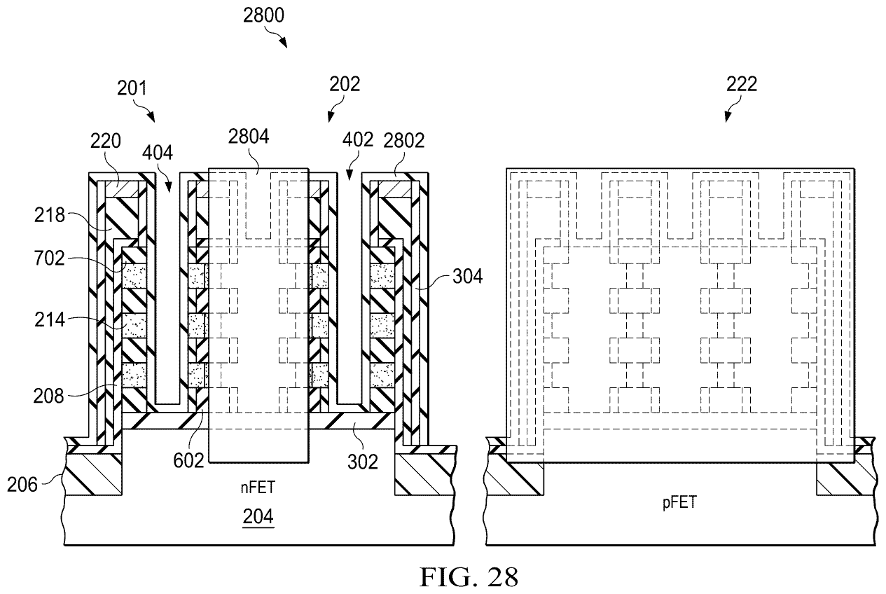

Turning now to FIGS. 28-33, illustrations for processing steps of forming a source in a nFET region are depicted. In view 2800 of FIG. 28, liner 2802 is visible covering both nFET region 202 and pFET region 222. In view 2800, nFET source patterning layer 2804 is depicted over semiconductor structure 201. In view 2800, nFET source patterning layer 2804 covers pFET region 222 and drain 2602. In view 2800, nFET source canyon 404 is exposed for etching. In view 2900 liner 2802 has been stripped from nFET source canyon 404 for processing. After stripping liner 2802 from nFET source canyon 404, nFET source patterning layer 2804 is removed, as depicted in view 3000.

Between view 3000 and view 3100, a lateral etch has been performed. The lateral etch removed portions of silicon nano sheet layers 214 adjacent nFET source canyon 404. The lateral etch removed portions of silicon nano sheet layers 214 within nFET region 202. The lateral etch removed silicon nano sheet layers 214 to EG oxide 208 and channels 2502. In some illustrative examples, the etching may be referred to as a “lateral push”. The lateral push between view 3000 and view 3100 removes remaining silicon nano sheet layers 214 in nFET region 202.

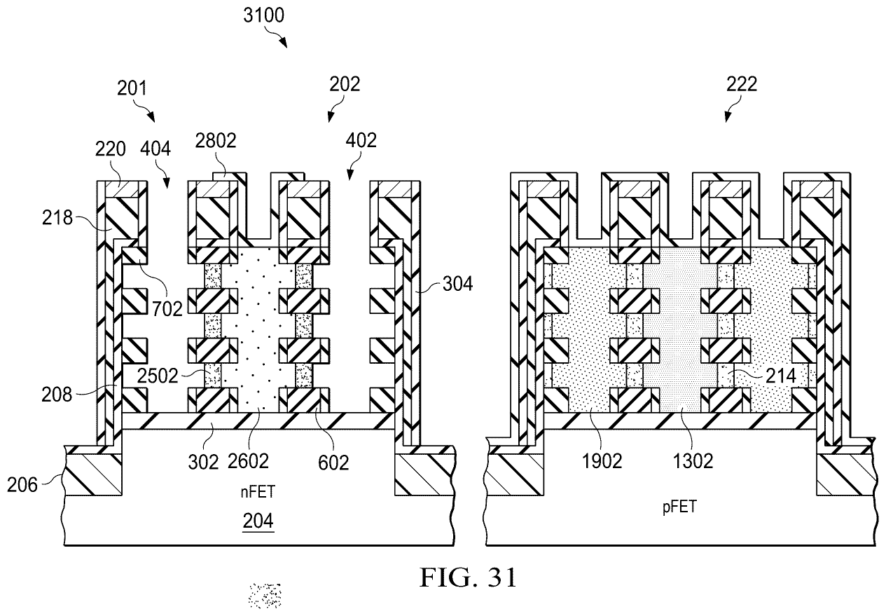

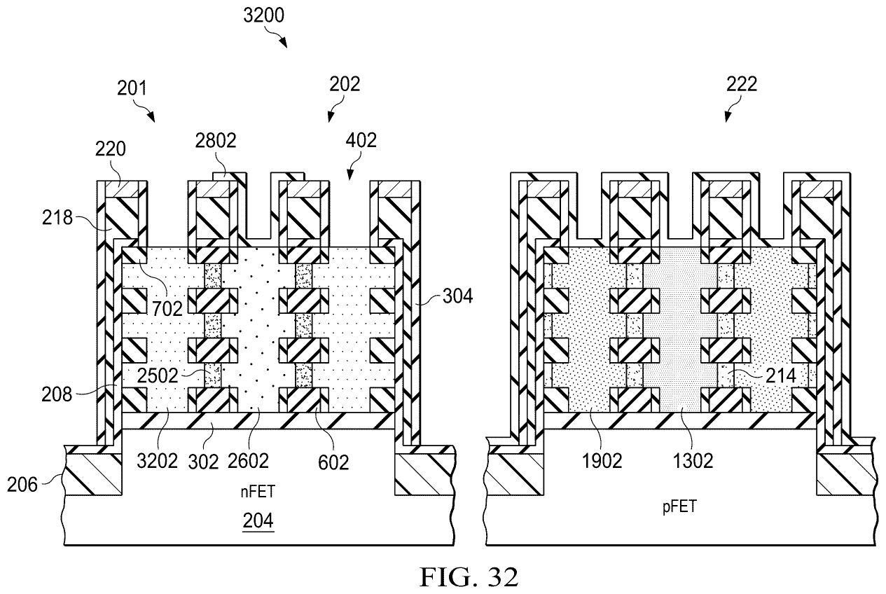

Referencing FIG. 32, an illustration of a cross-sectional view of a semiconductor device in a nFET region and a pFET region of a semiconductor wafer after a source growth is depicted in accordance with an illustrative embodiment. In view 3200, source 3202 has been epitaxially grown within nFET source canyon 404. In some illustrative examples, source 3202 comprises GaSb. Due to the lateral push depicted in view 3100 of FIG. 31, source 3202 extends past channel spacers 702.

After depositing source 3202, a liner strip is performed to remove liner 2802 from semiconductor structure 201. In view 3300, liner 2802 has been removed and semiconductor structure 201 is ready for further processing to perform gate formation, middle of line (MOL), and back end of line (BEOL) processing.

In FIGS. 15-33 the method of forming a p-i-n junction semiconductor device has repeatedly, until each of the source and the drain for both the nFET region and the pFET region have been formed, performed the steps of: laterally etching into the channel material sheets past the inner spacer in at least one respective canyon of the plurality of canyons to form respective lateral recesses; and epitaxially growing a remaining material of the source or the drain for each of the nFET region or the pFET region in the at least one respective canyon including the respective lateral recesses.

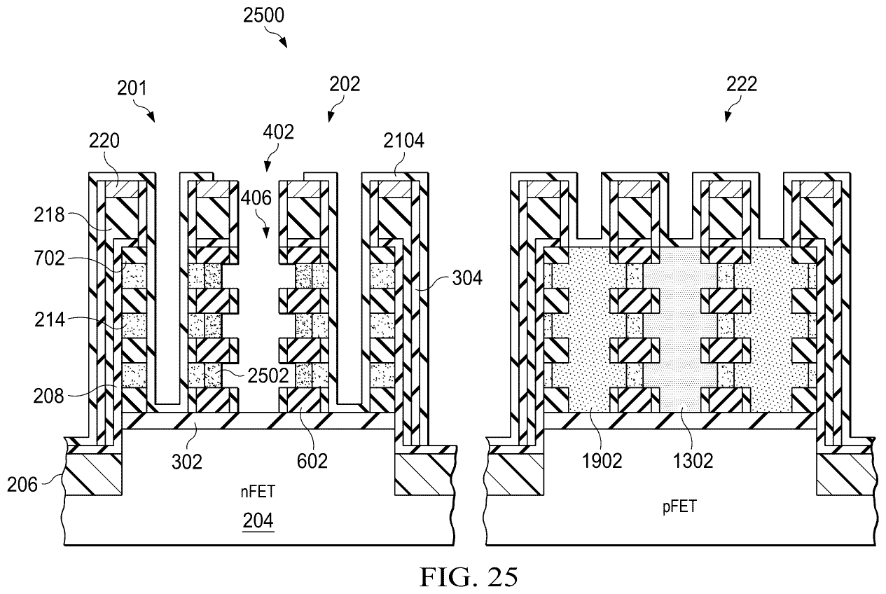

In FIGS. 24 and 31, the method of forming a p-i-n junction semiconductor device has performed etching out the channel material sheets in the nFET region prior to epitaxially growing the source and the drain of the nFET region. In FIG. 25, the method of forming a p-i-n junction semiconductor device has performed epitaxially growing a second channel material in the nFET region prior to epitaxially growing the source and the drain of the nFET region. In the depicted illustrative example, epitaxially growing the remaining material of the source or the drain for each of the nFET region or the pFET region in the at least one respective canyon including the respective lateral recesses in the method of forming a p-i-n junction semiconductor device comprises epitaxially growing a different material for each of the source and the drain of the nFET region or the pFET region.

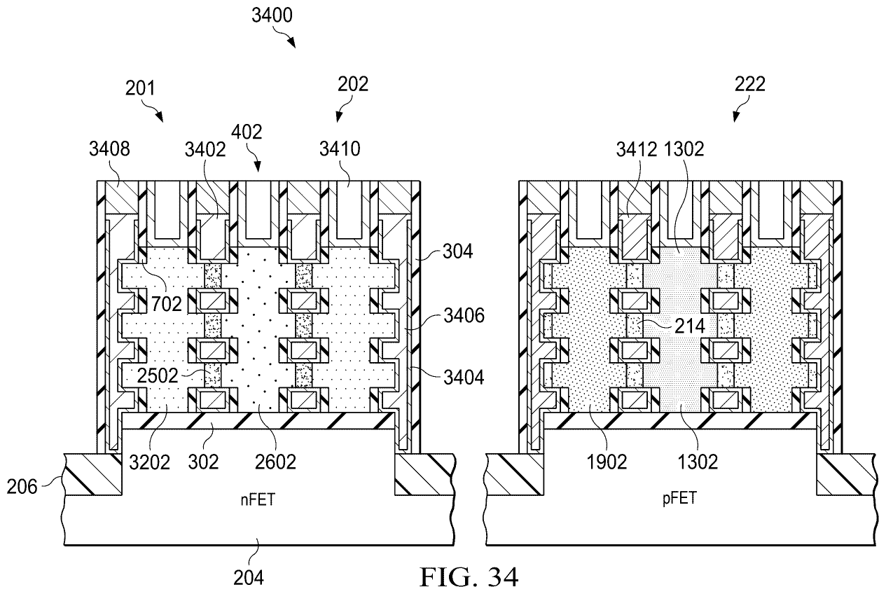

Turning now to FIG. 34, an illustration of a cross-sectional view of a semiconductor device in a nFET region and a pFET region of a semiconductor wafer after gate formation is depicted in accordance with an illustrative embodiment. Asymmetric silicon (aSi) layer 218 and hard mask 220 are present for patterning during the processing and forming of nFET and pFET devices in FIGS. 2-33. Asymmetric silicon (aSi) layer 218 and hard mask 220 have been removed in view 3400 to form gate stacks in later processing steps.

Removal of the dummy gates and spacer material in the gate regions has been performed between view 3300 and view 3400. A gate stack comprising a high-k material and a work function metal (WFM) and self-aligned contact (SAC) capping layers are formed between view 3300 and view 3400.

The method of forming a p-i-n junction semiconductor device has performed forming a gate in contact with a channel material sheet of the channel material sheets and directly contacting an entire circumference of an interface between the channel material sheets and the source in the at least one channel, the gate comprising a high-k dielectric and work force metal.

In view 3400 gates 3402 have been formed in nFET region 202 and pFET region 222. Gates 3402 in nFET region 202 are formed of different materials than gates 3402 in pFET region 222. A gate dielectric material is provided as high-K dielectric material 3404. Gates 3402 of nFET region 202 further comprise n-work function material 3406. N-work function material 3406 can comprise one of TiN, TiC, TiAl, TaN, or any combination thereof.

Gates 3402 in pFET region 222 comprise high-K dielectric material 3404. Gates 3402 of pFET region 222 further comprise p-work function material 3412. SAC cap 3408 is present over gates 3402.

Liner 3410 is a sacrificial layer above the S/D regions. Liner 3410 is formed of any desirable material. After gate formation, liner 3410 will be removed and contacts will be formed.

Referring to FIG. 35, view 3500 includes semiconductor structure 3501. Semiconductor structure 3501 includes nFET region 3502 and pFET region 3534. These areas can be co-located on a single substrate. The nFET region 3502 and pFET region 3534 can be heterogeneously integrated with STI 3506 (shallow trench isolation).) The embodiment show in FIG. 35 does not have a self-aligned substrate isolation layer. The nFET region 3502 includes substrate 3504. Substrate 3504 can be intrinsic p-SI substrate.

Drain 3508 is located between two portions of source 3510. Drain 3508 can be epitaxially deposited n+InAs. Source 3510 can be epitaxially deposited p-GaSb. In this embodiment, there are six of channel 3512 located between drain 3508 and source 3510. Channel 3512 can be epitaxially deposited intrinsic n-InAs. There is a gate including WFM 3514 (work function metal) and HK 3516 (high k dielectric) all around the six of channel 3512. Inner spacer 3517 is adjacent HK 3516 in non-channel sheet areas. Spacer 3518 is adjacent HK 3516 in areas outboard of source 3510.

SAC cap 3520 is coupled to a top of WFM 3514. Contact (CA) 3522 is coupled to a top of drain 3508 and a top of source 3510. CA ILD 3524 is located between contact (CA) 3522. Via (VA) ILD 3526 is coupled to a top of CA ILD 3524. Via (VA) 3528 is coupled to a top of contact (CA) 3522. Metal 1 (M1) ILD 3530 is coupled to a top of via (VA) ILD 3526. Metal 1 (layer (M1) 3532 is coupled to a top of via (VA) ILD 3526 and a top of via (VA) 3528.

The pFET region 3534 is structurally similar except for the via connections and some of the materials. Drain 3536 is located between two portions of source 3538. Drain 3536 can be epitaxially deposited p+Si. Source 3538 can be epitaxially deposited n+InAs. In this embodiment, there are six of channel 3540 located between drain 3536 and source 3538. Channel 3540 can be epitaxially deposited intrinsic p-Si. Located at the bottom of the drain 3508 and both portions of the source 3542 is a concave etch into substrate 3504. Of course, embodiments of this disclosure are not limited to the examples shown in FIG. 35.

Referring to either nFET region 3502 or pFET region 3534, the depicted embodiment is a p-i-n junction semiconductor device that includes: an extrinsically doped drain; an extrinsically doped source; a first intrinsically doped tunneling channel coupled between the extrinsically doped drain and the extrinsically doped source; a second intrinsically doped tunneling channel coupled between the extrinsically doped drain and the extrinsically doped source; and a gate coupled to both the first intrinsically doped tunneling channel and the second intrinsically doped tunneling channel. An axis defined by the extrinsically doped drain and an axis defined by the extrinsically doped source are substantially parallel, and the second intrinsically doped tunneling channel is stacked with regard to the first intrinsically doped tunneling channel along both the axis defined by the extrinsically doped drain and the axis defined by the extrinsically doped source. The p-i-n junction semiconductor device also includes: another extrinsically doped source; a third intrinsically doped tunneling channel coupled between the another extrinsically doped source; and another gate coupled to both the another extrinsically doped source and the third intrinsically doped tunneling channel. The axis defined by the extrinsically doped drain, the axis defined by the extrinsically doped source, and an axis defined by another extrinsically doped source are substantially coplanar. The p-i-n junction semiconductor device also includes: a drain via coupled to the extrinsically doped drain; a gate via coupled to the gate; and a source via coupled to the extrinsically doped source. The gate includes a work function metal coated with a high k dielectric. Referring to nFET region 3502, the first intrinsically doped tunneling channel and the second intrinsically doped tunneling channel include epitaxially deposited intrinsic n-InAs. Referring to pFET region 3534, the first intrinsically doped tunneling channel and the second intrinsically doped tunneling channel include epitaxially deposited intrinsic p-Si.

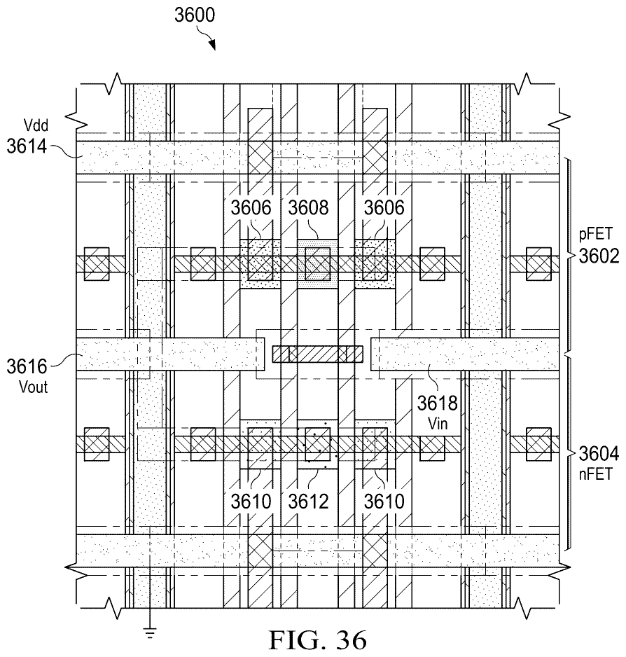

Referring to FIG. 36, a view of semiconductor structure 3600 is shown. In this example of practical integration into a specific technological context, the structure includes a tFET inverter/RO. The tFET is a non-ambipolar, reverse-biased, p-i-n junction. Thus, Vdd/ground are swapped compared to a MOSFET. The structure includes both pFET region 3602 and nFET region 3604.

The structure includes pFET source 3606. The structure includes pFET drain 3608. The structure includes nFET source 3610. The structure includes nFET drain 3612. Vdd 3614 is coupled to the nFET source 3610. Vout 3616 is coupled to both the pFET drain 3608 and nFET drain 3612. Vin 3618 is coupled to the gates of both pFET region 3602 and nFET region 3604. The pFET source 3606 is coupled to ground. Of course, embodiments of this disclosure are not limited to the example shown in FIG. 36.

The illustrative examples provide a p-i-n junction with horizontal gate all around (hGAA). The illustrative examples, provide overlapping entire intrinsic region and both p-i and i-n junction interfaces. The illustrative examples provide a hGAA p-i-n junction device. In the illustrative examples, the gate (HK+WFM) directly contacts the entire circumference of the source-channel interface and the entire intrinsic region.

In some illustrative examples, multiplicity of stacked devices is possible. In the illustrative examples, nFET and pFET are integrated on same wafer with different materials and/or doping used for p-i-n junctions/channels. The illustrative examples present a low-power nanosheet device. Stacking TFETs allow the device to overcome low drive current.

In the illustrative examples, the entire heterogenous structure is co-integrated onto Si substrate. In the illustrative examples, the source and drain S/D are asymmetric. In some illustrative examples, the semiconductor device can be co-integrated with self-aligned substrate isolation layer (SASI)/BDI. In some illustrative examples, the semiconductor device can have indented Fin below nanosheet (NS) stack, where S/D/channel Epi is re-grown.

The illustrative examples present a method to form GAA-TFETs integrated on Si nanosheet architecture. The method uses POR nanosheet process flow up to Fin recess. The method comprises a SiGe60 release when present. The method comprises a sacrificial channel replacement with dielectric. The method comprises inner spacer formation. Alternating canyons are formed for the S/D. One of S/D patterning for one of the nFET or pFET to open alternating canyons is performed. A lateral Si push to middle of gate is performed. Channel and/or S/D epi growth is performed. The S/D patterning, lateral Si push, and channel and/or epi growth steps are performed for a single one of a source or a drain of a nFET or a pFET. Afterwards, the S/D patterning, lateral Si push, and channel and/or epi growth steps are performed for the remaining 3 channel/junction epi growths. After formation of the 3 channel/junction epi growths, the remainder of POR POC, RMG, MOL, and BEOL process flow are performed.

The illustrative examples present the first ever GAA stacked nanosheet tunnel FET and a method to form GAA-TFETs integrated on Si Nanosheet Architecture.

The illustrative method follows at least 80% of standard nanosheet integration prior to formation of the GAA stacked nanosheet tunnel FET.

The illustrative examples provide channel/source epi growth unilaterally off of a single surface and crystal orientation. Growth off of different materials provide different crystal planes as nucleation points. Different crystal planes can lead to different types of undesirable impacts on the crystal lattice. Epi growth unilaterally off of a single material can be beneficial to the channel.

The illustrative examples provide direct contact of gate (HK/WFM) to the source-channel boundary for optimal control of band-to-band tunneling. The illustrative examples present a scalable way to monolithically integrate p and n type TFETs on Si substrate. The illustrative examples are implemented on a nanosheet architecture.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A p-i-n junction semiconductor device, comprising:
an extrinsically doped drain;
a first extrinsically doped source;
a first intrinsically doped tunneling channel coupled between the extrinsically doped drain and the first extrinsically doped source;
a second extrinsically doped source;
a second intrinsically doped tunneling channel coupled between the extrinsically doped drain and the second extrinsically doped source; and
a gate coupled to both the first intrinsically doped tunneling channel and the second intrinsically doped tunneling channel,
wherein an axis defined by the extrinsically doped drain, an axis defined by the first extrinsically doped source, and an axis defined by the second extrinsically doped source are all substantially parallel.

2. The p-i-n junction semiconductor device of claim 1, wherein the axis defined by the extrinsically doped drain, the axis defined by the first extrinsically doped source, and the axis defined by the second extrinsically doped source are substantially coplanar.

3. The p-i-n junction semiconductor device of claim 1, further comprising:
a drain via coupled to the extrinsically doped drain;
a gate via coupled to the gate;
a first source via coupled to the first extrinsically doped source; and
a second source via coupled to the second extrinsically doped source.

4. The p-i-n junction semiconductor device of claim 1, further comprising a self-aligned substrate isolation layer coupled between a substrate and all of the extrinsically doped drain, the first extrinsically doped source, and the second extrinsically doped source.

5. The p-i-n junction semiconductor device of claim 1, wherein the gate comprises a work function metal coated with a high k dielectric.

6. The p-i-n junction semiconductor device of claim 1, wherein the first intrinsically doped tunneling channel and the second intrinsically doped tunneling channel comprise epitaxially deposited intrinsic n-InAs.

7. The p-i-n junction semiconductor device of claim 1, wherein the first intrinsically doped tunneling channel and the second intrinsically doped tunneling channel comprise epitaxially deposited intrinsic p-Si.

8. A p-i-n junction semiconductor device, comprising:
an extrinsically doped drain;
an extrinsically doped source;
a first intrinsically doped tunneling channel coupled between the extrinsically doped drain and the extrinsically doped source;
a second intrinsically doped tunneling channel coupled between the extrinsically doped drain and the extrinsically doped source; and
a gate coupled to both the first intrinsically doped tunneling channel and the second intrinsically doped tunneling channel,
wherein an axis defined by the extrinsically doped drain and an axis defined by the extrinsically doped source are substantially parallel, and
wherein the second intrinsically doped tunneling channel is stacked with regard to the first intrinsically doped tunneling channel along both the axis defined by the extrinsically doped drain and the axis defined by the extrinsically doped source.

9. The p-i-n junction semiconductor device of claim 8, further comprising:
another extrinsically doped source;
a third intrinsically doped tunneling channel coupled between the another extrinsically doped source; and
another gate coupled to both the another extrinsically doped source and the third intrinsically doped tunneling channel.

10. The p-i-n junction semiconductor device of claim 8, wherein the axis defined by the extrinsically doped drain, the axis defined by the extrinsically doped source, and an axis defined by another extrinsically doped source are substantially coplanar.

11. The p-i-n junction semiconductor device of claim 8, further comprising:
a drain via coupled to the extrinsically doped drain;
a gate via coupled to the gate; and
a source via coupled to the extrinsically doped source.

12. The p-i-n junction semiconductor device of claim 8, further comprising a self-aligned substrate isolation layer coupled between a substrate and all of the extrinsically doped drain, the extrinsically doped source, and the gate.

13. The p-i-n junction semiconductor device of claim 8, wherein the gate comprises a work function metal coated with a high k dielectric.

14. The p-i-n junction semiconductor device of claim 8, wherein the first intrinsically doped tunneling channel and the second intrinsically doped tunneling channel comprise epitaxially deposited intrinsic n-InAs.

15. The p-i-n junction semiconductor device of claim 8, wherein the first intrinsically doped tunneling channel and the second intrinsically doped tunneling channel comprise epitaxially deposited intrinsic p-Si.

16. A method of forming a p-i-n junction semiconductor device comprising:
etching a plurality of canyons for sources and drains through a nanosheet stack of channel material sheets and sacrificial layers;
etching out the sacrificial layers of the nanosheet stack;
depositing a dielectric sacrificial material in the nanosheet stack;
etching the plurality of canyons into the dielectric sacrificial material;
laterally etching into the dielectric sacrificial material in the plurality of canyons;
depositing an inner spacer into the plurality of canyons;
etching the plurality of canyons into the inner spacer;
laterally etching into the channel material sheets past the inner spacer in at least one canyon of the plurality of canyons to form lateral recesses; and
epitaxially growing one of a source or a drain in the at least one canyon including the lateral recesses.

17. The method of claim 16, wherein epitaxially growing one of the source or the drain comprises epitaxially growing one of the source or the drain for one of a nFET region or a pFET region, the method further comprising:
repeatedly, until each of the source and the drain for both the nFET region and the pFET region have been formed, performing the steps of:
laterally etching into the channel material sheets past the inner spacer in at least one respective canyon of the plurality of canyons to form respective lateral recesses; and
epitaxially growing a remaining material of the source or the drain for each of the nFET region or the pFET region in the at least one respective canyon including the respective lateral recesses.

18. The method of claim 17 further comprising:
etching out the channel material sheets in the nFET region prior to epitaxially growing the source and the drain of the nFET region; and
epitaxially growing a second channel material in the nFET region prior to epitaxially growing the source and the drain of the nFET region.

19. The method of claim 17, wherein epitaxially growing the remaining material of the source or the drain for each of the nFET region or the pFET region in the at least one respective canyon including the respective lateral recesses comprises epitaxially growing a different material for each of the source and the drain of the nFET region or the pFET region.

20. The method of claim 16 further comprising:
forming a gate in contact with a channel material sheet of the channel material sheets and directly contacting an entire circumference of an interface between the channel material sheets and the source in the at least one channel, the gate comprising a high-k dielectric and work force metal.
